(19) United States
(12) Patent Application Publication
(10) Pub. No.: US 2024/0130150 A1
(43) Pub. Date: Apr. 18, 2024

(54) LIGHT EMITTING DEVICE AND METHOD OF MANUFACTURING THE SAME

(71) Applicant: Oregon State University, Corvallis, OR (US)

(72) Inventors: Li-Jing Cheng, Corvallis, OR (US); Ahasan Ullah, Corvallis, OR (US)

(73) Assignee: Oregon State University, Corvallis, OR (US)

(21) Appl. No.: 18/475,182

(22) Filed: Sep. 26, 2023

Related U.S. Application Data
(60) Provisional application No. 63/413,238, filed on Oct. 4, 2022.

(51) Int. Cl. H10K 50/115; H10K 50/15; H10K 50/16; H10K 50/17; H10K 50/828; H10K 71/60

(52) U.S. Cl. CPC H10K 50/115; H10K 50/15; H10K 50/16; H10K 50/171; H10K 50/828; H10K 71/60; H10K 2101/90

(57) ABSTRACT

Described is a light emitting diode (LED) that uses hybrid nanostructures to enhance light emission intensity and light extraction efficiency. In at least one embodiment, nanostructures comprise a combination of metal and metal oxide layers that simultaneously provide optical property for emission enhancement and support electrical property for charge transport to support electroluminescence. In at least one embodiment, LED comprises multiple layers including a hybrid metal-metal oxide layer, light-emissive layer, and a light outcoupling layer. In at least one embodiment, metal-metal oxide layer can be formed by evaporation or sputtering. In at least one embodiment, light-emissive layer can be formed by emissive layer spin coating. In at least one embodiment, light outcoupling layer is formed by imprinting or by particle lithography.

### CLAIM FOR PRIORITY

This application claims priority to U.S. Provisional Patent Application No. 63/413,238, filed on Oct. 4, 2023, titled “LIGHT EMITTING DEVICE AND METHOD OF MANUFACTURING THE SAME,” and which is incorporated by reference in entirety.

### BACKGROUND

Micro light-emitting diode (micro-LED) is an emerging self-emissive device for a new generation of display technology because of its excellent brightness, resolution, lifetime, and low power consumption. Full-color micro-LEDs can be implemented by using group III-nitride-based semiconductor quantum well structures to produce red-blue-green (RGB) LED units. The LED units are then assembled to form a pixel array on a panel using a tedious mass transfer technique.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1A illustrates a photoluminescence (PL) based light-emitting diode (LED) that leverages the interaction between quantum dots (QDs) and metal nanoparticles in the color conversion layer to enhance light emission, in accordance with at least one embodiment.

FIG. 1B illustrates an electroluminescence (EL) based LED that combines metamaterial for emission enhancement and nanophotonic structure for efficient light outcoupling, in accordance with at least one embodiment.

FIG. 2 illustrates dispersion relations of a dielectric material and multilayered hyperbolic metamaterials (HMMs) of two different types, in accordance with at least one embodiment.

FIG. 3A illustrates a photograph and cross-sectional scanning electron microscope (SEM) image of an HMM sample, in accordance with at least one embodiment.

FIG. 3B illustrates effective permittivity at horizontal and vertical direction of the HMM sample, in accordance with at least one embodiment.

FIG. 3C illustrates an iso-frequency plot, in accordance with at least one embodiment.

FIG. 3D illustrates a plot showing fluorescence lifetime of a quantum dot (QD) layer on glass and the HMM measured by a time-correlated single-photon counting (TCSPC) system, in accordance with at least one embodiment.

FIG. 4A illustrates a cross-sectional SEM image of a QD-coated HMM covered by a monolayer array of polystyrene nanoparticles (PS-NP), in accordance with at least one embodiment.

FIG. 4B illustrates a large-area PS-NP array formed by a self-assembly method, in accordance with at least one embodiment.

FIG. 4C illustrates a PL spectrum of the QD coated on glass, glass cover by a PS-NP array, HMM, and HMM covered by a PS-NP monolayer array, in accordance with at least one embodiment.

FIG. 4D illustrates a wavevector G supported by nanophotonic structure which assists the outcoupling of light from HMM to the free space, in accordance with at least one embodiment.

FIG. 4E illustrates electrical filed profiles of the QD emitter in a 20 nm thick polymer layer on HMM with PS-NP, in accordance with at least one embodiment.

FIG. 4F illustrates electrical filed profiles of the QD emitter in a 20 nm thick polymer layer on HMM without PS-NP array, in accordance with at least one embodiment.

FIGS. 4G-I illustrate normalized emission profiles of the QD layer coated on glass, HMM, and HMM covered by PS-NP array, respectively, in accordance with at least one embodiment.

FIG. 5A illustrates a plot showing calculated characteristic response |ε_{∥}·ε_{⊥}| of a multilayer HMM structure (e.g., Ag/NiO) as a function of Ag filling fraction and emission wavelength using Drude model, in accordance with at least one embodiment.

FIG. 5B illustrates a plot showing theoretical Purcell enhancement factor of a single quantum emitter located 10 nm from the surface of the structure as a function of Ag filling fraction and emission wavelength, in accordance with at least one embodiment.

FIGS. 6A-E illustrate fabrication steps of large-area nanostructure for light outcoupling, in accordance with at least one embodiment.

FIG. 7A illustrates a plot showing E-field profiles induced by a QD emitter in a 20 nm thick polymer layer on an HMM covered by a plasmonic hole array (inset), in accordance with at least one embodiment.

FIG. 7B illustrates a plot showing E-field profiles induced by a QD emitter in a 20 nm thick polymer layer between two HMM layers, in accordance with at least one embodiment.

FIG. 7C illustrates a plot showing E-field profiles induced by a QD emitter in a 20 nm thick polymer layer between two HMM layers with a plasmonic hole array covered on top for light extraction, in accordance with at least one embodiment.

FIG. 8A illustrates a structure of QD LED with a hole transport layer (HTL) (e.g., NiO) backed by HMM (e.g., Ag/NiO) for emission enhancement, in accordance with at least one embodiment.

FIG. 8B illustrates a dual HMM QD LED with both first HMM (e.g., Ag/NiO) and second HMM (e.g., Ag/ZnO) as a hole transport layer (HTL) and an electron transport layer (ETL), respectively, in accordance with at least one embodiment.

FIG. 9A illustrates an LED that may comprise multiple layers, including a cathode, HMM that serves as an electron transport layer (ETL) and contains an optional electron injection layer (EIL), a light-emitting layer, a hole transport layer (HTL), a hole injection layer (HIL), an anode, and a nanostructure for improving light outcoupling, in accordance with at least one embodiment.

FIG. 9B illustrates an LED that may comprise multiple layers, including an anode, HMM that serves as a hole transport layer (HTL) and contains an optional hole injection layer (HIL), a light-emitting layer, an electron transport layer (ETL), an optional electron injection layer (EIL), a cathode, and a nanostructure for improving light outcoupling, in accordance with at least one embodiment.

FIG. 9C illustrates an LED without light outcoupling structure, in accordance with at least one embodiment.

FIG. 10A illustrates a portion of an LED with HMM/EIL/ETL composite layer, formed over a cathode, which is a stack structure comprising an HMM layer, an optional EIL (5-40 nm thick), and a non-metallic ETL (e.g., 20 nm to 50 nm thick ZnO), in accordance with at least one embodiment.

FIG. 10B illustrates a portion of an LED with an interface layer (e.g., 5 nm Al₂O₃) that may be included over the ETL layer to eliminate exciton quenching, in accordance with at least one embodiment.

FIG. 10C illustrates a portion of an LED with a second ETL (e.g., 3 nm to 20 nm thick 1,3,5-tris(2-N-phenylbenzimidazolyl)benzene (TPBi)) that may be formed over the ETL to improve current injection, in accordance with at least one embodiment.

FIG. 10D illustrates a portion of an LED with a second ETL over the first ETL, and an interface layer over second ETL which may be used in the structure, in accordance with at least one embodiment.

FIG. 11 illustrates a method of forming an LED, in accordance with at least one embodiment.

### DETAILED DESCRIPTION

Colloidal quantum dots (QDs) are promising emissive materials for micro-LED that form a display panel without complicated mass transfer processes. Advantages of colloidal QDs for LEDs are their narrow emission linewidth, high photoluminescence (PL) quantum yield, high photostability, and low fabrication cost. Narrow emission linewidth enables more saturated colors in displays. QD-based micro-LED displays are mainly realized by PL or electroluminescence (EL). In PL-based micro-LEDs, QDs are physically embedded in polymer matrices to form a color conversion layer that converts ultra-violet (UV) micro-LED excitation light to red-green-blue (RGB) colors. If blue excitation micro-LEDs are used, red and green color-conversion materials are used. EL-based LEDs utilize a layer of colloidal QDs to convert recombination of electrons and holes injected from electrodes to photons. QD-based EL LEDs may exhibit external quantum efficiency (EQE) of about 20% for RGB colors, approaching performance of phosphorescent OLEDs, which have the EQE of about 30%. QD micro-LED displays may outperform display competitors, including OLED displays.

PL and EL-based LEDs may not fully convert light excitation or injected current to radiative emissions. Also, a limited percentage of generated photons can escape device to free space due to various light confinements in device. Nonradiative emission and photon absorption in LEDs result in high energy consumption and reduced device lifetime. Therefore, it is desirable to apply additional techniques to increase radiative emission rate of QDs and to promote light outcoupling from device to enhance overall quantum efficiency.

In at least one embodiment, an LED is provided that uses hybrid nanostructures to enhance light emission intensity and light extraction efficiency. In at least one embodiment, nanostructures comprise a combination of metal and metal oxide layers that simultaneously provide the optical property for emission enhancement and support the electrical property for the charge transport to support electro-luminescence. In at least one embodiment, LED comprises multiple layers including a hybrid metal-metal oxide layer, light-emissive layer, and a light outcoupling layer. In at least one embodiment, metal-metal oxide layers can be formed by evaporation or sputtering. In at least one embodiment, light-emissive layers can be formed by the emissive layer spin coating. In at least one embodiment, light outcoupling layers are formed by imprinting or by particle lithography.

At least one embodiment combines (1) planar metamaterial that engineers local density of optical state (LDOS) to enhance QDs' radiative emission rate, and (2) nanophotonic structures to enlarge outcoupling of emitting light into free space. In at least one embodiment, planar metamaterial comprises materials that provide optical property for emission enhancement and support electrical property to function as charge transport layer of an EL-based micro-LED. In at least one embodiment, nanophotonic structures are fabricated on topmost layer of LED device to promote light outcoupling.

There are many technical effects of various embodiments. For example, structure of LED enhances emission efficiency of LED, and thus emission efficiency of displays comprising such LEDs. Unlike devices that utilize nanostructure at bottom of device for light enhancement, planar metamaterial of at least one embodiment offers a smooth surface to allow conformal coverage of an individual device layer and therefore sustain reliability of device.

At least one embodiment will be understood more fully from detailed description given below and from the accompanying drawings, which, however, should not be taken to limit disclosure to at least one embodiment, but are merely for explanation and understanding.

In the following description, numerous details are discussed to provide a more thorough explanation of at least one embodiment. It will be apparent, however, to one skilled in the art, that at least one embodiment may be practiced without these specific details. In other instances, well-known structures and devices are shown in block diagram form, rather than in detail, to avoid obscuring at least one embodiment.

Note that in corresponding drawings, signals are represented with lines. Some lines may be thicker, to indicate more constituent signal paths, and/or have arrows at one or more ends, to indicate primary information flow direction. Such indications are not intended to be limiting. Rather, lines are used in connection with at least one embodiment to facilitate easier understanding of a circuit or a logical unit. Any represented signal, as dictated by design needs or preferences, may actually comprise one or more signals that may travel in either direction, and may be implemented with any suitable type of signal scheme.

It is pointed out that those elements of the figures having the same reference numbers (or names) as the elements of any other figure can operate or function in any manner like that described but are not limited to such.

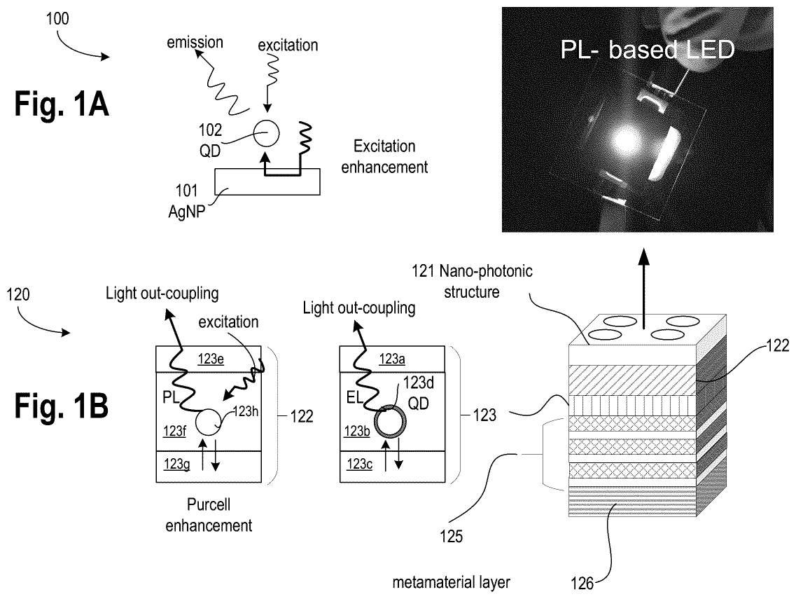

FIG. 1A illustrates a photoluminescence (PL) based LED 100, in at least one embodiment. In at least one embodiment, LED 100 comprises metal nanoparticles (NP) 101 and quantum dots (QDs) 102. In at least one embodiment, LED 100 leverages interaction between quantum dots 102 and metal nanoparticles in color conversion layer to enhance light emission. In at least one embodiment, metal NP 101 comprises Ag.

FIG. 1B illustrates an electroluminescence (EL) based LED 120, in at least one embodiment. In at least one embodiment, LED 120 comprises a nanophotonic structure 121, electrode 122 (e.g., anode or cathode), layers of metal nanoparticles (e.g., 123a, 123c, 123e, and 123g) and NP QDs (e.g., 123d in layer 123b and 123h in layer 123f) collectively labeled as 123, metamaterial and charge transport layers 125, and electrode 126 (e.g., cathode or anode). In at least one embodiment, for an electroluminescence (EL) based LED, QD has an outer metal layer (e.g., QD 123d). In at least one embodiment, outer metal layer is a metal thin film comprising Ag. In at least one embodiment, for a photoluminescence (PL) based LED, QD has no outer metal layer (e.g., QD 123h).

In at least one embodiment, LED 120 combines metamaterial and charge transport layers 125 for emission enhancement and nanophotonic structure 121 for efficient light outcoupling. In at least one embodiment, metamaterial and charge transport layers 125 also serves as a charge transport layer. At least one embodiment metamaterial 125 combines (1) planar metamaterial that engineers local density of optical state (LDOS) to enhance QDs' radiative emission rate, and (2) nanophotonic structures to enlarge outcoupling of emitting light into free space.

In at least one embodiment, planar metamaterial comprises materials that provide optical property for emission enhancement and support electrical property to function as charge transport layer of an EL-based micro-LED. In at least one embodiment, nanophotonic structures are fabricated on topmost layer of LED device to promote light outcoupling.

Unlike devices that utilize nanostructure at bottom of a device for light enhancement, in at least one embodiment, planar metamaterial offers a smooth surface to allow conformal coverage of each device layer and therefore sustain reliability of device. In at least one embodiment, LED 120 combines metamaterial-nanophotonic structures to enhance radiative emission and light outcoupling of a QD emissive layer. In at least one embodiment, LED 120 demonstrates enhanced electroluminescence using the QD LED with the combined structure.

In at least one embodiment, enhanced radiative emission is achieved through engineering of local density of optical states (LDOS). In at least one embodiment, spontaneous emission rate of a quantum emitter depends on its surrounding photonic environment characterized by the LDOS. In at least one embodiment, LDOS counts number of photon modes accessible for emission in a specific region of space. In at least one embodiment, a large LDOS provides more radiative decay pathways and, thus, larger radiative decay rates. In at least one embodiment, derived from Fermi's Golden Rule, spontaneous emission rate F r of a QD emitting light at an angular frequency of w is given by:

$${Γ}_{r} = \frac{πω}{3 {ℏϵ}_{0}} {\vert p \vert}^{2} ρ ( r , ω )$$

where p is transition dipole moment of emitter, r is position, and ε₀ is permittivity of free space. In at least one embodiment, LDOS ρ(r,ω) ∝ \hat{n}ₚ·Im[ [symbol] (r,r)]·\hat{n}ₚ, where \hat{n}ₚ is orientation of transition emitter dipole and [symbol] (r,r) is dyadic Green's function, which describes electric field interacting with emitter due to its own radiation. In at least one embodiment, LDOS is highly dependent on structure's geometry and permittivity. In at least one embodiment, by engineering electromagnetic environment of a quantum emitter (e.g., LDOS), emission of quantum emitter can be enhanced.

In at least one embodiment, spontaneous emission rate of a quantum emitter can be modified when located inside a resonant cavity. In at least one embodiment, Purcell factor, FP, and quantifying emission rate Γᵣ inside the cavity compared to its value in vacuum Γ₀ is proportional to a ratio of cavity mode quality factor Q and its effective volume V_{eff}, i.e., Fₚ=Γᵣ/Γ₀ ∝ Q/V_{eff}. It may be challenging to design a cavity to achieve a strong emission rate by maximizing ratio because of the tradeoff between a large Q factor and a small effective volume V_{eff}. A microcavity, for instance, gives an ultrahigh Q (e.g., approximately 109) but takes a large effective volume (thousands μm³). In at least one embodiment, diffraction-limited mode volume can be obtained by coupling emitters to photonic crystals or a nanofiber. In at least one embodiment, an alternative way to downscale effective volume is to utilize surface plasmon polaritons (SPPs).

In at least one embodiment, SPPs are tightly confined electromagnetic waves propagating along metal surfaces and are not diffraction limited. In at least one embodiment, resonant surface waves support additional modes that increase LDOS in a subwavelength scale. In at least one embodiment, SPPs have a significantly reduced effective volume that ensures an efficient coupling rate with quantum emitters.

In at least one embodiment, light emitters thar located at near-field of a metal surface tend to release their energies through three major routes—radiative emission, nonradiative decay, and plasmonic modes. In at least one embodiment, metal nanostructures can interact with light emitters in near field to control spontaneous emission dynamics. In at least one embodiment, resonant coupling of emitters with surface plasmons lead to observation of photoluminescence (PL) enhancement and quenching depending on distance between emitter and metal, with accompanying changes in excited state lifetime. In at least one embodiment, an optimal distance between emitter and metal for strongest emission enhancement is about 5 nm, below which fluorescence quenching starts occurring. In at least one embodiment, emission enhancement tends to be more observable when the quantum emitter couples to an electric field hot spot produced by localized surface plasmon resonance (LSPR).

In at least one embodiment, enhanced emission in a PL-based micro-LED is achieved using a color conversion layer composed of a mixture of QDs and metal nanoparticles, as shown in FIG. 1A. In at least one embodiment, metal nanoparticles absorb excitation light and convert to SPP that excites QDs with increased energy, enhancing light emission. In at least one embodiment, metal nanoparticles can also serve as scatterers to promote light extraction. In at least one embodiment, effect of excitation enhancement on PL intensity induced by metal nanoparticles may not be observed in a counterpart that uses dielectric nanoparticles, such as ZnO, TiO₂, or ZrO nanoparticles, to improve light extraction through scattering.

In at least one embodiment, to enhance emission rate of QD emissive layer in an EL-based micro-LED, QD emissive layer is placed on top of a multilayered hyperbolic metamaterial (HMM), which provides optical property to support large LDOS and simultaneously offers electrical property to serve as a charge transport layer. Here, HMMs are uniaxial media where components of permittivity tensor have opposite signs in two orthogonal directions.

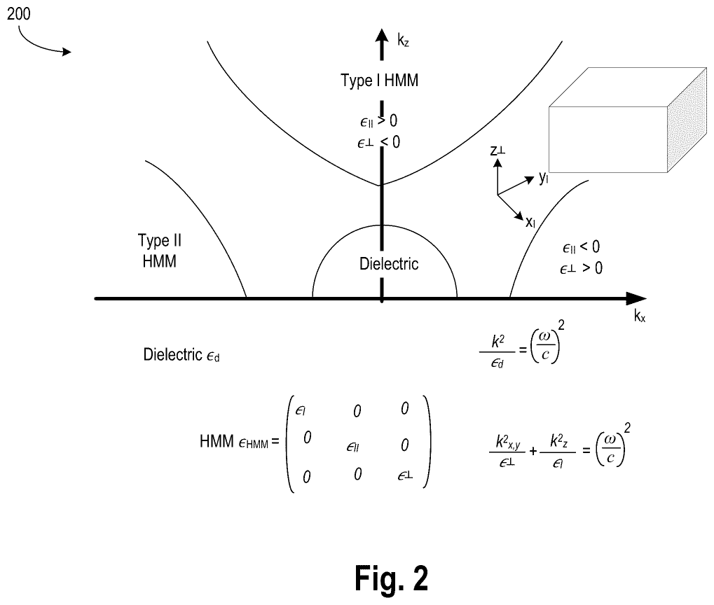

FIG. 2 illustrates plot 200 showing dispersion relations of a dielectric material and multilayered hyperbolic metamaterials (HMMs) of two different types, in accordance with at least one embodiment. As illustrated in FIG. 2, most of natural materials are isotropic media with a dispersion relation of k²/ε_{d}32 (ω/c)² that defines a spherical iso-frequency surface in k-space. In at least one embodiment, closed iso-frequency surface implies an upper cutoff of wavenumber and a finite LDOS. In at least one embodiment, dispersion relation of HMMs k_{x,y}²/ε_{⊥}+k_{z}²/ε_{∥}=(ω/c)² results in a hyperboloid iso-frequency surface in which permittivity show opposite signs e.g., ε_{⊥}·ε_{∥}<0.

In at least one embodiment, open iso-frequency surface of HMMs indicates support of propagating waves in bulk with unbounded wavevectors and existence of a broadband infinitely large LDOS, enabling instantaneous radiative decay and highly enhanced emission. In at least one embodiment, diverging LDOS in HMMs leads to a large Purcell effect in a broadband spectrum. In at least one embodiment, hyperbolic dispersion relation yields an infinite LDOS that enables the QD in vicinity of a large spontaneous emission rate. In at least one embodiment, when light emitters are brought into near-field of an HMM, an additional decay route arises due to coupling of emitted evanescent waves to high-k modes of HMM while emission into propagating waves is reduced. In at least one embodiment, large number of high-k modes in HMMs causes an enhancement in spontaneous emission. In at least one embodiment, a substantial enhancement may be observed in spontaneous emission rates of organic fluorophores and quantum dots when deposited near surface of HMMs.

Obtaining a large Purcell factor using HMMs may not guarantee a large radiative power output detectable in free space. QD light emissions may mostly couple to HMMs as high-k propagating waves which can hardly emit to far-field. In at least one embodiment, to make Purcell enhancement useful, an outcoupling mechanism can be built with HMM for light extraction. In at least one embodiment, by introducing defect scatterers or periodicity in HMMs to create photonic crystal features, it is possible to observe out-of-plane emission to far-field. In at least one embodiment, by patterning an HMM into one-dimensional (1D) grating, spontaneous emission rate of fluorescent dye molecules can be enhanced, for example by 76-fold, and its fluorescence intensity increases, e.g., by about 80-fold, compared with uniform HMM. In at least one embodiment, a high-refractive-index-contrast bullseye grating made of germanium can out-couple high-k waves of quantum dot emission in an HMM. At least one embodiment utilizes nanophotonic structures to extract the enhanced radiation by coupling high-k waves propagating within HMMs into low-k modes.

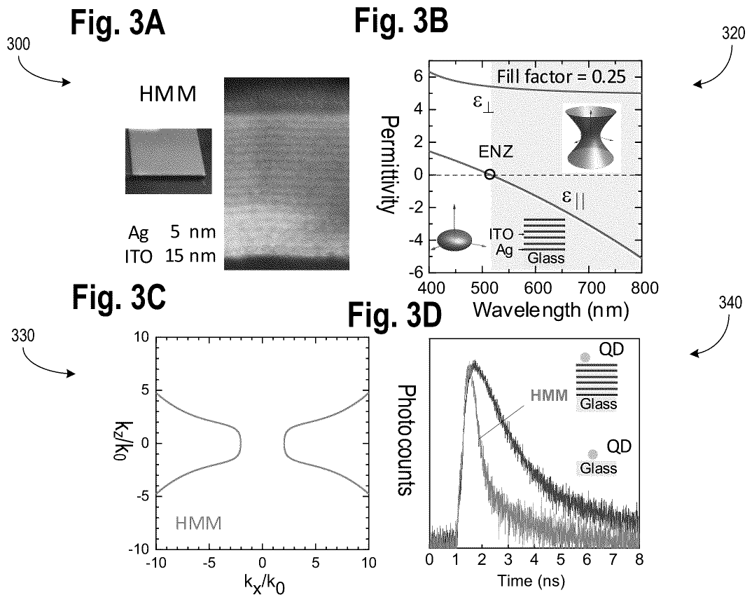

FIG. 3A illustrates a photograph and cross-sectional SEM image of an HMM sample 300, in accordance with at least one embodiment. In at least one embodiment, HMM comprises alternating Ag/indium tin oxide (ITO) multilayers with an Ag filling fraction of 0.25.

FIG. 3B illustrates plot 320 showing effective permittivity at horizontal and vertical direction of an HMM sample, in accordance with at least one embodiment. In at least one embodiment, filling fraction can be chosen to achieve a hyperbolic permittivity (ε_{⊥}>0 and ε_{∥}<0) for wavelength greater than epsilon near zero (ENZ) condition at about 520 nm as shown in FIG. 3B.

FIG. 3C illustrates iso-frequency plot 330, in accordance with at least one embodiment. In at least one embodiment, hyperboloid iso-frequency in a k-space indicates that HMM supports unbounded wavevectors and an infinitely large LDOS.

FIG. 3D illustrates plot 340 showing fluorescence lifetime of a QD layer on glass and HMM measured by a time-correlated single-photon counting (TCSPC) system, in accordance with at least one embodiment. In at least one embodiment, fluorescence lifetime of CdSe QDs on HMM and glass are measured to be 0.41 ns and 2.54 ns, respectively (FIG. 3D). This result agrees with theoretical prediction that HMM surface supports large LDOS that increases radiative emission rate and therefore reduces fluorescence lifetime of QDs. At least one embodiment demonstrates extraction of enhanced QD emission from HMM surface with an optical outcoupling technique.

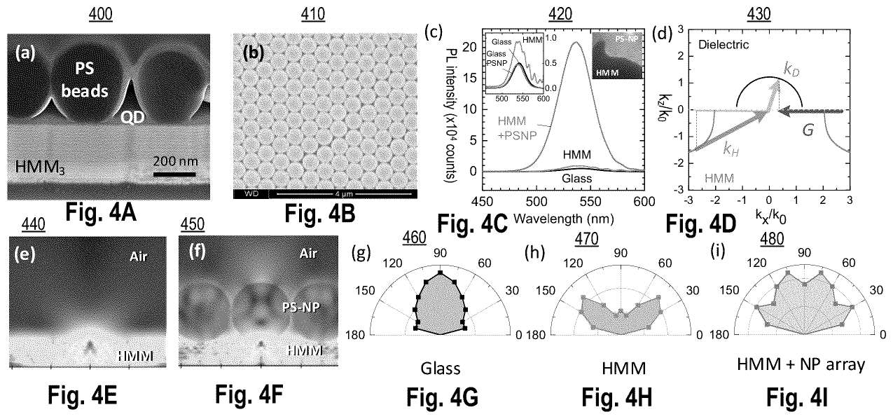

FIG. 4A illustrates a cross-sectional SEM image 400 of a QD-coated HMM covered by a monolayer array of polystyrene nanoparticles (PS-NP), in accordance with at least one embodiment.

FIG. 4B illustrates large-area PS-NP array 410 formed by a self-assembly method, in accordance with at least one embodiment. FIG. 4A and FIG. 4B show cross-sectional and top-view SEM image in plot 440 and SEM image in plot 450, respectively, of a QD-coated HMM covered by a monolayer array of polystyrene nanoparticles (PS-NP), in accordance with at least one embodiment.

FIG. 4C illustrates plot 420 showing PL spectra of QD coated on glass, glass cover by a PS-NP array, HMM, and HMM covered by a PS-NP monolayer array, in accordance with at least one embodiment. Here, inset is a fluorescence image of QD coated HMM with and without PS-NP array, in accordance with at least one embodiment. In at least one embodiment, PL spectra of QDs on glass, and HMM in inset of FIG. 4C appear to be very weak, even though QDs emission rate is enhanced by HMM, evidenced by reduced fluorescence lifetime in FIG. 3D. In at least one embodiment, adding a monolayer PS-NP array increases the emission intensity of the QDs on HMM by, for example, more than 20 times, which can also be observed in fluorescence image in inset of FIG. 4C. In at least one embodiment, emission intensity is about 40 times as strong as the QDs on glass. In at least one embodiment, adding the PS-NP array on the QD-coated glass may not improve emission intensity. In at least one embodiment, PS-NP array efficiently extracts the high-k waves from the HMM to the free space. In at least one embodiment, emission enhancement may be produced by QD's interaction with HMM and becomes visible via an outcoupling technique.

FIG. 4D illustrates plot 430 showing wavevector G supported by nanophotonic structure which assists the outcoupling of light from HMM to free space, in accordance with at least one embodiment.

FIG. 4E illustrates plot 440 showing electrical filed profiles of QD emitter in a 20 nm thick polymer layer on HMM with PS-NP, in accordance with at least one embodiment.

FIG. 4F illustrates plot 450 showing electrical filed profiles of QD emitter in a 20 nm thick polymer layer on HMM without PS-NP array, in accordance with at least one embodiment.

FIGS. 4G-I illustrate normalized emission profiles 460, 470, and 480 of QD layer coated on glass, HMM, and HMM covered by PS-NP array, respectively, in accordance with at least one embodiment.

Light outcoupling can be explained by iso-frequency plot at HMM-dielectric interface in FIG. 4D, in accordance with at least one embodiment. In at least one embodiment, periodic nanostructure supports a wavevector G that allows high-k waves k_{H} in HMM to fulfill momentum conservation in the direction parallel to interface, e.g., k_{H∥}+G=k_{D∥}, and couple to free space becoming a propagating wave km FDTD simulations in FIG. 4D and FIG. 4F show that without outcoupling mechanism, QD emission is trapped in HMM layer, while PS-NP couples light to free space. In at least one embodiment, emission profiles in FIGS. 4G-I indicate successful light extraction through a PS-NP array.

In at least one embodiment, emission enhancement and light outcoupling strategies may use further improvement to work with micro-LEDs for better performance. In at least one embodiment, HMM structure with different materials is used to enhance emission rate of QDs and simultaneously serve as hole or electron transport layer. In at least one embodiment, HMM structure describes a nanostructure to further improve extraction of high-k wave from HMM layer.

At least one embodiment creates an electrically conductive metal/semiconductor HMM to support Purcell enhancement of QD emission. At least one embodiment optimizes light outcoupling nanostructures using a printed nanoparticle monolayer. At least one embodiment describes a QD LED enhanced by integrated HMM and outcoupling nanostructures.

Following section describes QD LED enhanced by the integration of multilayered HMM and plasmonic light outcoupling structures, in accordance with at least one embodiment. At least one embodiment describes HMMs based on alternating Ag/semiconductor multilayers to support large Purcell effect of specific quantum dot emission wavelengths. In at least one embodiment, semiconductor layer in HMM is made of NiO or ZnO. In at least one embodiment, NiO and ZnO have proper permittivity function to form HMM structure with Ag layers. In at least one embodiment, p-type and n-type semiconducting properties of NiO and ZnO may function as hole- and electron-transport layers, respectively, in LEDs.

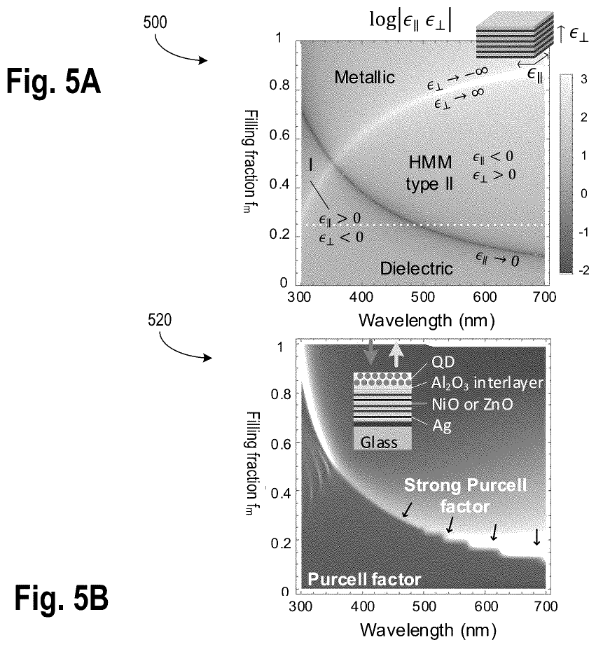

FIG. 5A illustrates plot 500 showing calculated characteristic response |ε_{∥}·ε_{⊥}| of an Ag/NiO multilayer HMM structure as a function of Ag filling fraction and emission wavelength using Drude model, in accordance with at least one embodiment. In at least one embodiment, optical properties of device structure comprise Ag/NiO or Ag/ZnO multilayered HMM on a glass substrate. In at least one embodiment, HMM with minimized unit cell (a metal/semiconductor pair) thickness may be employed. In at least one embodiment, minimum thickness of each layer may be 5 nm, determined by fabrication capability of an RF sputtering tool. In at least one embodiment, total thickness of HMM may range between 60 nm and 250 nm, comparable to thickness of electron/hole transport layers in LEDs.

In at least one embodiment, topmost layer of the HMM may be semiconductor oxide layer that interfaces a QD layer to enable enhanced emission and efficient carrier injection while minimizing any photo-quenching. In at least one embodiment, a QD layer less than 50 nm may be formed on an HMM film by direct spin-coating of QD solutions or QD polymer mixtures. In at least one embodiment, core-shell CdSe/ZnS QDs of multiple emission wavelengths may be applied. In at least one embodiment, should direct contact of QDs to NiO semiconductor surface quench QD emission due to high density of free charge carriers in NiO, a thin Al₂O₃ interlayer may be deposited by atomic layer deposition (ALD) to separate QD layer and NiO top layer to eliminate exciton quenching.

In at least one embodiment, multiple effects on emission enhancement are investigated, including (1) metal filling fraction in HMMs, (2) numbers of HMM unit cells, (3) presence of Al₂O₃ interlayer, and (4) different QD emission wavelengths ranging from 620 nm to 470 nm. QD fluorescence lifetime is evaluated using Time-Correlated Single Photon Counting (TCSPC) to analyze the enhancement factors of QDs on HMMs of different structure dimensions and materials. In at least one embodiment, luminescence and quantum yields (QY) of these samples may be measured through PL characterization. In at least one embodiment, with both lifetime and QY measurements, radiative and nonradiative emission rates of the QDs are extracted under different optical environments.

FIG. 5B illustrates plot 520 showing theoretical Purcell enhancement factor of a single quantum emitter located 10 nm from the surface of the structure as a function of Ag filling fraction and emission wavelength, in accordance with at least one embodiment. In at least one embodiment, design of HMM structure may be based on a theoretical optical characteristic response (ε_{∥}·ε_{⊥} product) and a theoretical Purcell factor of multilayer HMM structure as a function of Ag filling fraction and wavelength as depicted in FIG. 5B. In at least one embodiment, multilayered HMM structure exhibits optical property of HMM type II regime, which yields a strong Purcell factor with the Ag filling fraction between 0.15 and 0.3. In at least one embodiment, optical property of HMM type II regime can be even stronger when ε_{∥} approaches zero, e.g., ENZ along lateral polarizations.

In at least one embodiment, QDs placed on top of HMM experience an asymmetrical LDOS that restricts maximum Purcell factor attainable. In at least one embodiment, Purcell effect can be much stronger when these light emitters are embedded inside the HMM rather than on its surface. In at least one embodiment, spontaneous emission enhancement inside a multilayer HMM can reach a maximum of almost 300-fold, 3 times larger than its peak value for an external emitter. In at least one embodiment, emission enhancement is achieved by placing QD layer within HMM structure. In at least one embodiment, this can be implemented in an EL-based LED in which the NiO and ZnO charge transport layers are replaced by the Ag/NiO and Ag/ZnO HMM structure.

Following section describes dimension effect of HMM charge transport layers on luminescence property of the emitting layer. At least one embodiment identifies extraction of high-k waves from HMM using self-assembled nanoparticle monolayer that results in a 40-fold increase in PL intensity compared with QDs coated on glass.

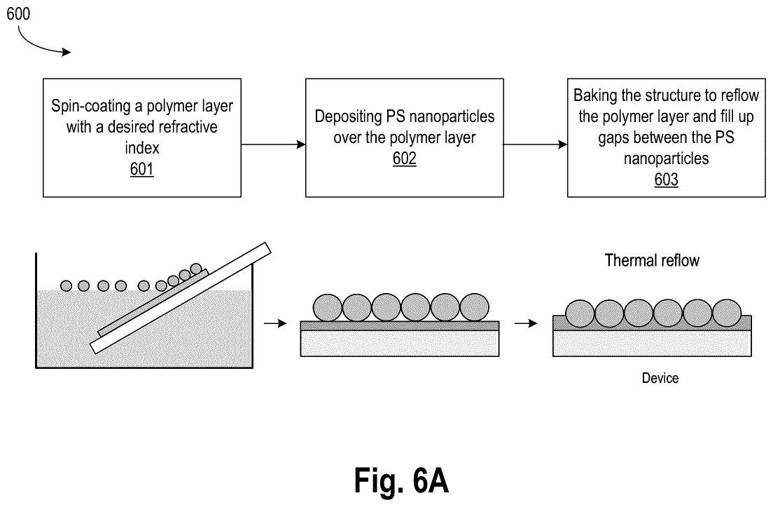

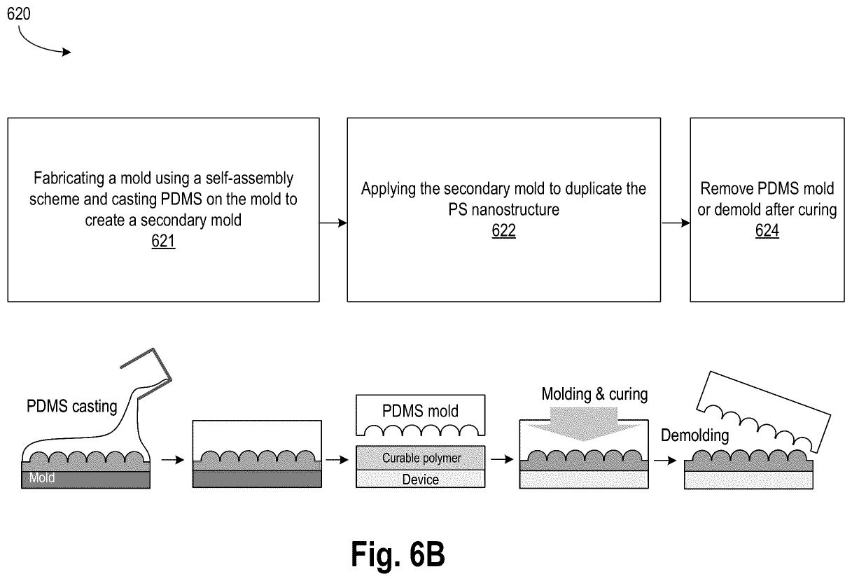

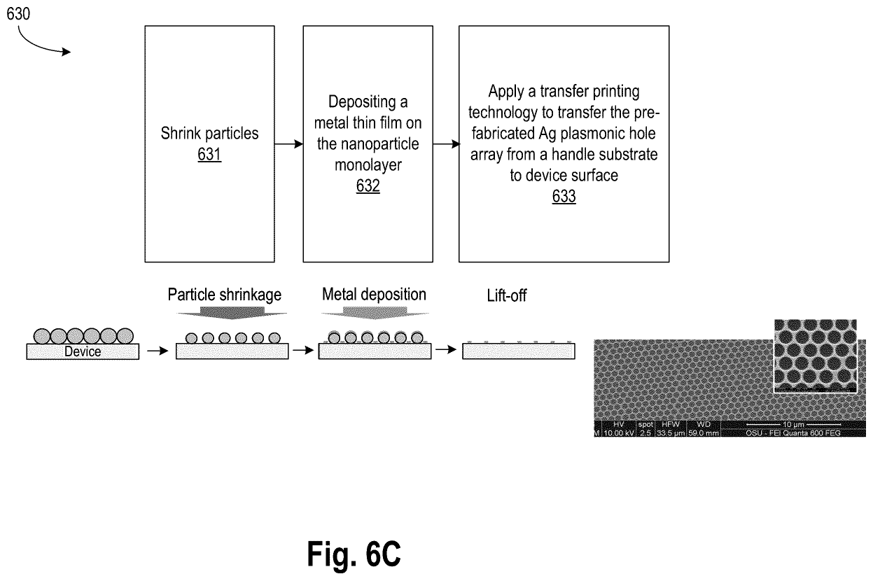

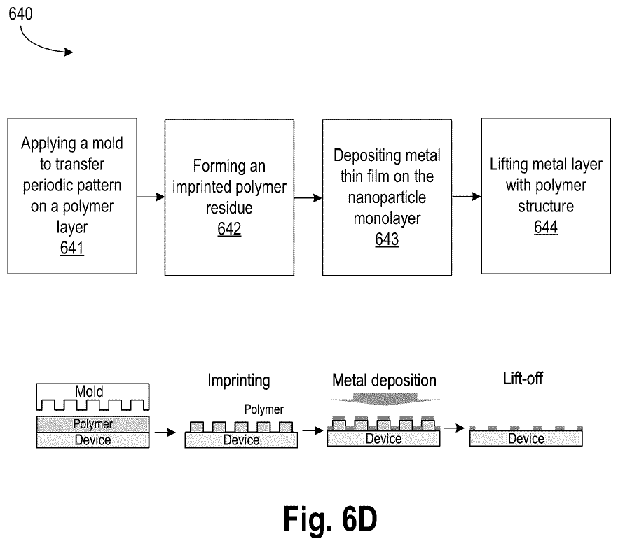

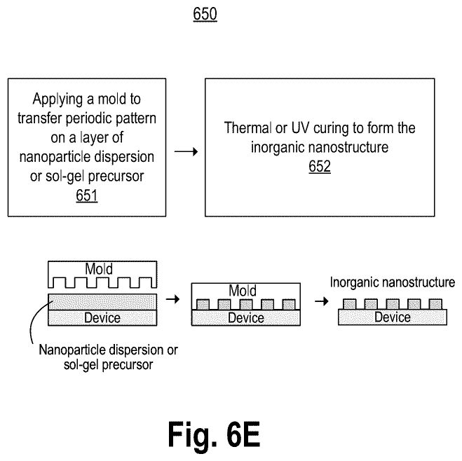

FIGS. 6A-C illustrate fabrication processes 600, 620, and 630, respectively, of large-area nanostructure for light outcoupling, in accordance with at least one embodiment. Comparing with conventional nanolithography techniques based on electron-beam lithography and focused ion beam mealing, nanoparticle self-assembly technique of at least one embodiment allows formation of large-area periodic nanostructure. On the basis of this nanofabrication technology, different strategies are described to improve light outcoupling efficiency by using (1) nanoparticle array without air gaps and (2) nanoplasmonic structures processed by imprinting and pattern transfer methods, in accordance with at least one embodiment.

In one of the new device schemes, at least one embodiment shows that it is possible to extract more light from HMM by filling up air gaps between nanoparticle and HMM surface. Finite-Difference Time-Domain (FDTD) simulations show that air gaps between nanoparticle monolayer structures may create a large difference in refractive index across an HMM surface that prevents release of high-k waves to free space. In at least one embodiment, increasing refractive index of gaps between PS-NPs enhances light extraction. In at least one embodiment, an optimal refractive index may be slightly lower than that of polystyrene nanoparticles (e.g., n of approximately 1.59). At least one embodiment optimizes light outcoupling efficiency by tuning nanoparticle size and the corresponding refractive index in gaps. Based on this design, nanoparticle self-assembly technique may be modified to fabricate the structure, in accordance with at least one embodiment.

FIG. 6A illustrates fabrication process 600 and corresponding self-assembly and polymer reflow, in accordance with at least one embodiment. FIG. 6A illustrates a fabrication process to achieve a structure comprising nanoparticle monolayer with gaps filled by a high refractive index polymer layer. At block 601, in at least one embodiment, a polymer layer with a desired refractive index is spin-coated on a device surface, e.g., a QD-coated HMM. In at least one embodiment, size of PS nanoparticle may determine polymer layer thickness for proper filling of inter-particle gaps. At block 602, in at least one embodiment, PS nanoparticles monolayer is deposited over polymer surface using Langmuir-Blodgett self-assembly method. At least one embodiment improves hydrophilicity of polymer surface by a short oxygen plasma or surfactant treatment to better control self-assembly process. At block 603, in at least one embodiment, after formation of nanoparticle monolayer, structure is baked to reflow polymer layer and fill up gaps between particles. In at least one embodiment, a polymer with a glass transition temperature (Tg) lower than that of PS is applied for this process. In at least one embodiment, candidate polymer materials for this process include poly(methyl acrylate) PMA, poly(methyl methacrylate) PMMA, etc.

FIG. 6B illustrates fabrication process 620 and associated molding and curing flow, in accordance with at least one embodiment. In at least one embodiment, an alternative molding method is described in FIG. 6B which allows for creating homogeneous nanostructures with inter-particle gaps filled by the same polymer material as nanoparticles. At block 621, in at least one embodiment, a mold is fabricated using the same self-assembly method, and gap filling process describes previously. At least one embodiment further casts PDMS on mold to create a secondary mold which will then be used to duplicate nanostructure on device using thermally curable or UV-curable polymer. At block 622, in at least one embodiment, secondary mold is applied to duplicate PS nanostructure. In at least one embodiment, thermally curable or UV-curable polymer is used to duplicate nanostructure. At block 624, in at least one embodiment, PDMS mold is removed or demolded after curing.

In at least one embodiment, periodic nanoplasmonic structures may also be exploited to out-couple high-k waves from HMM. At least one embodiment performs nanolithography using nanoparticle self-assembly technique to produce nanoplasmonic structure on an HMM device.

FIG. 6C illustrates fabrication process 630 and corresponding plasmonic nanostructure by nanoparticle lithography, in accordance with at least one embodiment. Inset here is an SEM image of a large-area Ag nanohole array (e.g., 700 nm period and 600 nm hole size over a 5 mm×5 mm area) fabricated using fabrication process 630 of FIG. 6C. At block 631, in at least one embodiment, nanoparticles or QDs are shrunk leaving gaps for metal deposition. In at least one embodiment, plasmonic outcoupling structure can be directly fabricated on device or transferred from a handle substrate to minimize damage of device during process. At block 632, in at least one embodiment, a periodic metal hole array is produced over a large area by depositing a metal thin film on nanoparticle monolayer followed by a metal lift-off process. In at least one embodiment, SEM images shows a periodic Ag nanohole array over an area greater than 5 mm by 5 mm. At block 633, in at least one embodiment, to minimize any process-induced device damage, a transfer printing technology is applied to transfer the pre-fabricated Ag plasmonic hole array from a handle substrate to the device surface.

FIG. 6D illustrates method 640 and corresponding nanoimprint lithography process for producing a periodic metal hole array over a large area, in accordance with at least one embodiment. At block 641, in at least one embodiment, a mold is applied to transfer a periodic pattern on a polymer layer. At block 642, in at least one embodiment, an imprinted polymer residue is formed after mold is applied to polymer layer. At bock 643, in at least one embodiment, metal thin film is deposited on imprinted polymer (e.g., nanoparticle monolayer). In at least one embodiment, a metal pattern is created by removing the imprinted polymer residue. At block 644, in at least one embodiment, metal layer with polymer layer or structure is lifted off.

FIG. 6E illustrates method 650 and corresponding nanoimprint process for producing a periodic inorganic material (e.g., titianum oxide) over a large area, in accordance with at least one embodiment. At block 651, in at least one embodiment, a mold is applied to transfer a periodic pattern on a layer of inorganic nanoparticle solution or inorganic sol gel. At block 652, in at least one embodiment, an imprinted inorganic structure is formed after mold is applied to a layer of inorganic nanoparticle dispersion or sol-gel precursor, followed by thermal or ultravoilet (UV) curing.

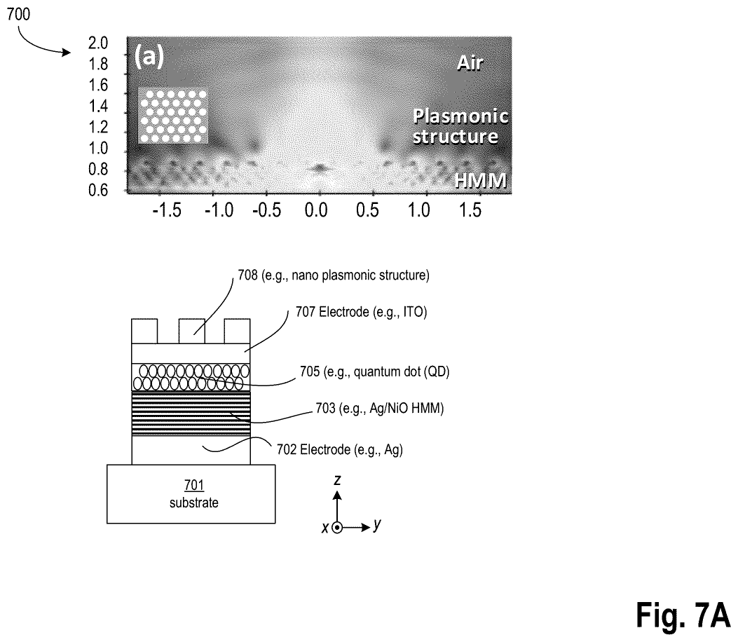

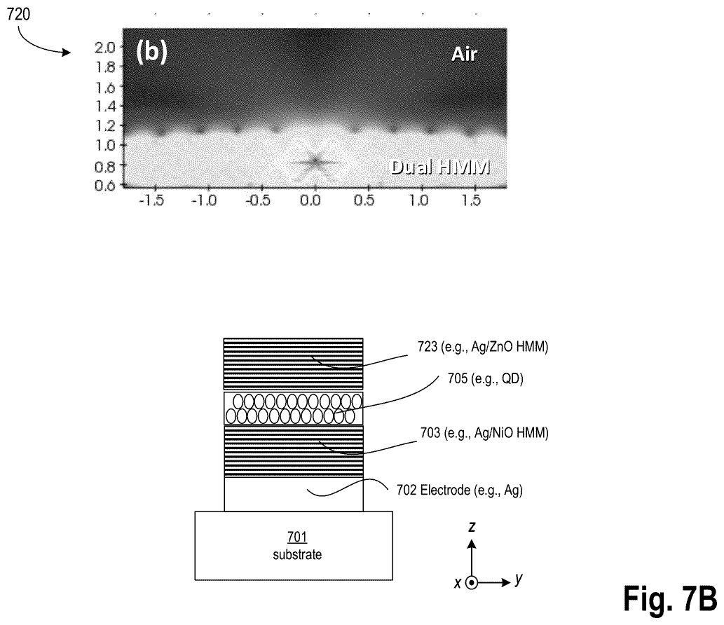

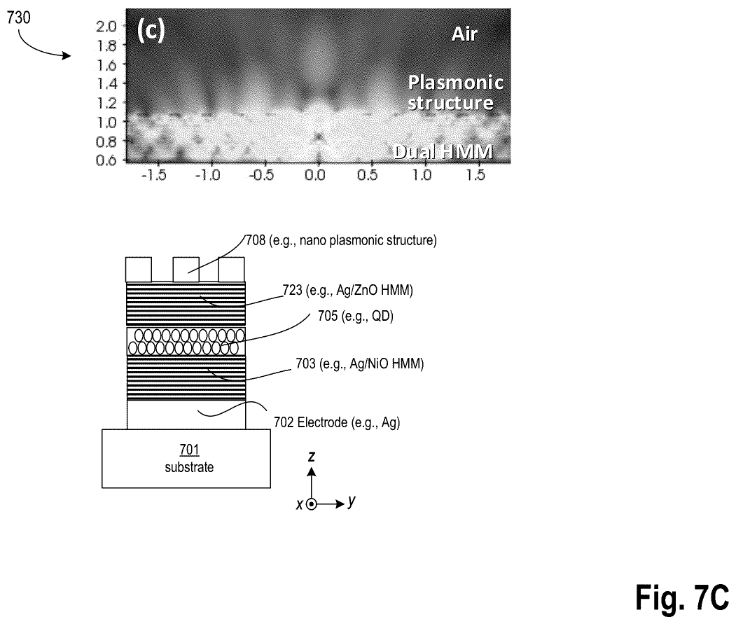

FIG. 7A illustrates plot 700 showing E-field profiles induced by a QD emitter in a 20 nm thick polymer layer on an HMM covered by a plasmonic hole array (inset), in accordance with at least one embodiment. In at least one embodiment, LED structure used for plot 700 includes substrate 701, electrode 702 (e.g., Ag), HMM layer 703 (e.g., alternating layers of Ag and NiO), QD layer 705, electrode 707 (e.g., ITO), and nano-plasmonic structure 708 coupled as shown. In at least one embodiment, FDTD simulation results in FIG. 7A demonstrates that 50 nm thick Ag plasmonic hole array with 200 nm hole size and 300 nm period efficiently out-couples light from QD-coated HMM.

FIG. 7B illustrates plot 720 showing E-field profiles induced by a QD emitter in a 20 nm thick polymer layer between two HMM layers, in accordance with at least one embodiment. In at least one embodiment, LED structure used for plot 720 includes substrate 701 (e.g., SiO₂), electrode 702 (e.g., Ag), first HMM layer 703 (e.g., alternating layers of Ag and NiO), QD layer 705, and second HMM layer 723 coupled as shown. Plot 720 shows that the QD layer 705 encapsulated between first HMM layer 703 (e.g., alternating layers of Ag and NiO) and second HMM layer 723 (e.g., alternating layers of Ag and ZnO) exhibits strong emission enhancement. In one such case, light may be trapped between first HMM layer 703 and second HMM layer 723.

FIG. 7C illustrates plot 730 showing E-field profiles induced by a QD emitter in a 20 nm thick polymer layer between two HMM layers with a plasmonic hole array covered on top for light extraction, in accordance with at least one embodiment. In at least one embodiment, LED structure used for plot 730 includes substrate 701, electrode 702 (e.g., Ag), first HMM layer 703 (e.g., alternating layers of Ag and NiO), QD layer 705, second HMM layer 723, and nano-plasmonic structure 708 (also referred to as nano-plasmonic hole array or plasmonic outcoupling structure) coupled as shown.

As shown in plot 730, nano-plasmonic structure 708 on dual HMM structure successfully extracts light to free space. FDTD simulations can be used to optimize design of plasmonic outcoupling structure, including hole size and period of repetitive holes. In at least one embodiment, position of dipole emitter relative to nanostructure may yield different emission profiles in free space. In at least one embodiment, performance of outcoupling methods herein are evaluated by characterization of PL spectra, intensity, and their emission profiles.

Following section demonstrates enhanced electroluminescence using QD LED with combined structure. In at least one embodiment, electroluminescence (EL) of QD LEDs is enhanced by incorporating HMM and light extraction structures.

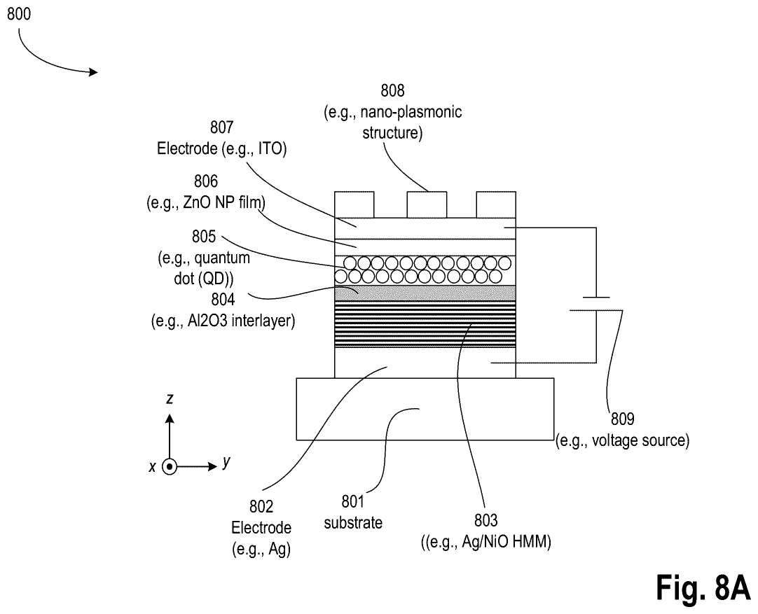

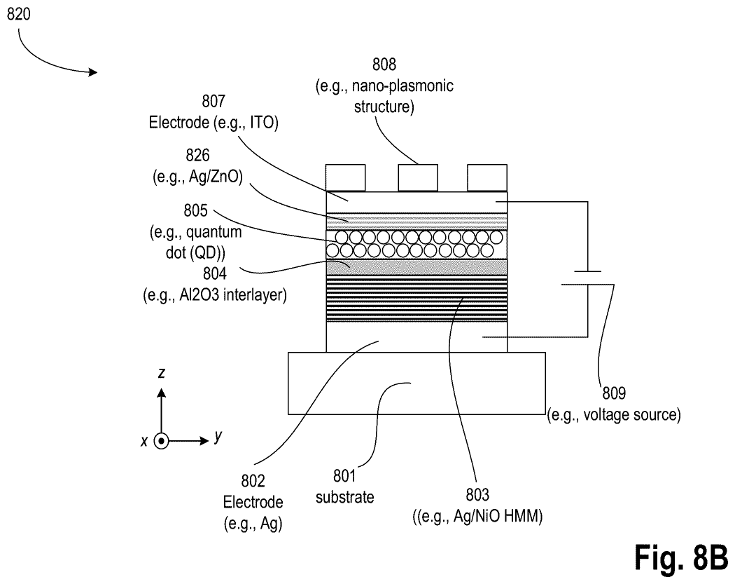

FIG. 8A illustrates QD LED 800 with an NiO hole transport layer (HTL) backed by an HMM (e.g., Ag/NiO) for emission enhancement, in accordance with at least one embodiment. In at least one embodiment, QD LED 800 comprises substrate 801, electrode 802, HMM 803 (e.g., Ag/NiO HMM), interlayer 804 (e.g., Al₂O₃), QD layer 805, NP film 806 (e.g., ZnO), electrode 807 (e.g., ITO), and nanoplasmonic structure 808 coupled as shown.

In at least one embodiment, first electrode 802 (e.g., Ag anode) has a thickness in z-direction of about 100 nm. In at least one embodiment, first HMM 803 (e.g., Ag/NiO multilayered HMM) has a thickness in z-direction of about 20 to 150 nm. In at least one embodiment, electrode 807 (e.g., ITO cathode) has a thickness in z-direction of about 100 nm. In at least one embodiment, first electrode 802, first HMM 803, and second electrode 807 are deposited using RF magnetron sputtering.

In at least one embodiment, interlayer 804 (e.g., Al₂O₃ interlayer) has a thickness in a z-direction of less than 5 nm. In at least one embodiment, interlayer 804 is deposited using atomic layer deposition (ALD) to mitigate possible quenching of QDs in QD layer 805 with direct contact to NiO surface of HMM 803. In at least one embodiment, interlayer 804 is between emissive QD layer 805 and HMM 803 which behaves as HTL. In at least one embodiment, interlayer 804 can eliminate unbalance of carrier injection. In at least one embodiment, interlayer 804 significantly improves performance of a QD LED via as carrier leakage. In at least one embodiment, QD layer 805 has a thickness of about 40 nm in a z-direction. In at least one embodiment, QD layer 805 is deposited by spin-coating. In at least one embodiment, NP film 806 (e.g., ZnO ETL) has a thickness of about 60 nm in a z-direction. In at least one embodiment, NP film 806 is fabricated by evaporation.

FIG. 8B illustrates dual HMM QD LED 820 with both first HMM (e.g., Ag/NiO) and second HMM (e.g., Ag/ZnO) as the HTL and ETL, respectively, in accordance with at least one embodiment. In at least one embodiment, QD LED 820 comprises substrate 801 (e.g., SiO₂), electrode 802 (e.g., anode comprising Ag), first HMM 803 (e.g., alternating layers of Ag and NiO HMM), interlayer 804 (e.g., Al₂O₃), QD layer 805, second HMM 826 (e.g., alternating layers of Ag and ZnO), electrode 807 (e.g., cathode comprising indium tin oxide (ITO)), and nano plasmonic structure 808 coupled as shown. In at least one embodiment, nano-plasmonic structure 808 on top of electrode 807 provides light extraction. In at least one embodiment, QD LED 820 uses a single NiO layer as hole transport layer (HTL) instead of alternating layers of Ag and NiO in first HMM 803.

In at least one embodiment, QD LED 820 is a top-emitting QD LED which emits light out of nano plasmonic structure 808. In at least one embodiment, QD LED 820 comprises a NiO hole transport layer (HTL) backed by first HMM 803 (e.g., NiO/Ag multilayered HMM) for EL enhancement. In at least one embodiment, first HMM 803 is an HTL. In at least one embodiment, interlayer 804 (e.g., Al₂O₃) is optional. In at least one embodiment, QD LED 820 comprises a nanoparticle layer that is configured as an electron transport layer (ETL) is formed over QD layer 805. In at least one embodiment, nano-plasmonic structure 808 is a nanoparticle (NP) monolayer which is configured for light extraction. In at least one embodiment, voltage source 809 is coupled to first electrode 802 and second electrode 807 to provide excitation for light generation.

In at least one embodiment, an HTL layer is formed above QD layer 805. In at least one embodiment, HTL layer has a thickness of about 20 nm in a z-direction. In at least one embodiment, emission enhancement is achieved for QD LED 820, relative to QD LED 800, by replacing NP film 806 (e.g., ZnO ETL film) with second HMM 826 (e.g., alternating layers of ZnO and Ag). In at least one embodiment, electrode 807 (e.g., top ITO cathode) is replaced with a transparent Ag layer. In at least one embodiment, transparent Ag layer has a thickness of 20 nm in a z-direction. In at least one embodiment, transparent Ag layer is formed by evaporation.

In at least one embodiment, ITO based electrode 807 (e.g., cathode) is replaced with a hole array (e.g., Ag based hole array) as a light extraction structure. In at least one embodiment, a transfer printing technique discussed herein is used to develop hole array.

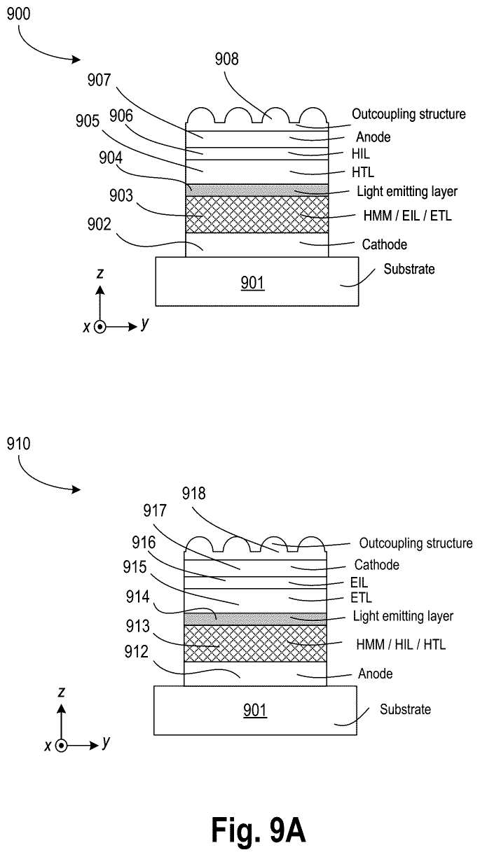

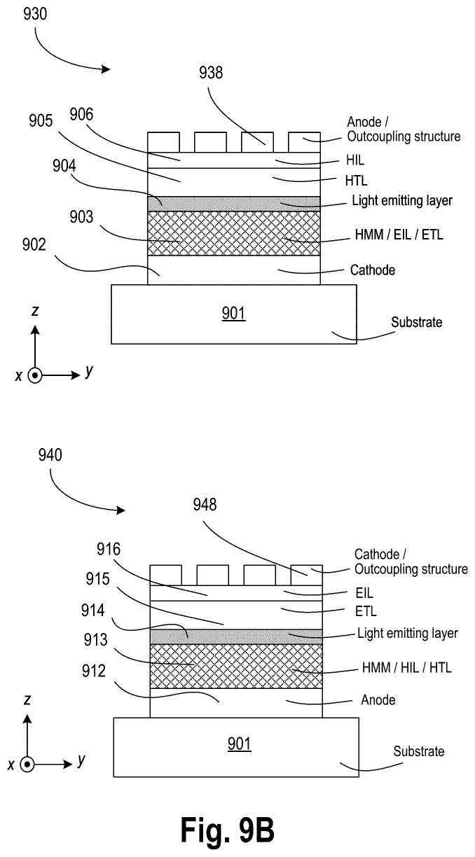

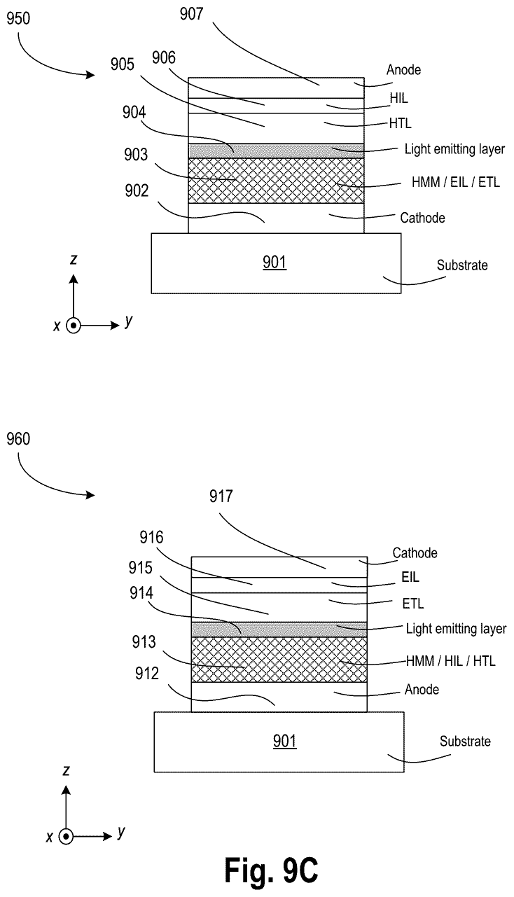

FIG. 9A illustrates LED 900, in accordance with at least one embodiment. In at least one embodiment, LED 900 comprises substrate 901 (e.g., SiO₂), cathode electrode 902, HMM 903, light emitting layer 904 (e.g., QD layer), hole transport layer (HTL) 905, hole injection layer (HIL) 906, anode electrode 907, and outcoupling structure 908 coupled as shown.

In at least one embodiment, hyperbolic metamaterial (HMM) 903 is configured to serve as an electron transport layer (ETL) and comprises an optional electron injection layer (EIL). In at least one embodiment, HMM 903 is configured to enhance light emission intensity. In at least one embodiment, HMM 903 comprises a combination of metal and metal oxide regions that simultaneously provide optical property for emission enhancement and serve as a charge transport layer (CTL) to support the electrical property for electroluminescence. In at least one embodiment, charge transport layer (CTL) can be an electron transport layer (ETL) or a hole transport layer (HTL). In at least one embodiment, a charge injection layer (CIL) can be an electron injection layer (EIL) or a hole injection layer (HIL). In at least one embodiment, HIL 905 may be used in contact between CTL and the anode electrode 906 to improve carrier injection efficiency. In at least one embodiment, outcoupling structure 908 is a nanostructure which is configured to improve light outcoupling by improving light extraction efficiency compared to LEDs without such nanostructure.

In at least one embodiment, LED 910 is similar to LED 900 but for locations of analog and cathode electrodes. In at least one embodiment, LED 910 comprises substrate 901, anode electrode 912, HMM 913, light emitting layer 914 (e.g., QD layer), electron transport layer (ETL) 915, electron injection layer (EIL) 916, cathode electrode 917, and outcoupling structure 918 coupled as shown. In at least one embodiment, HMM 913 is configured to function as HTL and HIL. In at least one embodiment, HMM 913 is a charge injection layer (CIL). In at least one embodiment, EIL 916 is between cathode electrode 917 and HMM 913 to improve carrier injection efficiency. In at least one embodiment, outcoupling structure 918 is a nanostructure which is configured to improve light outcoupling by improving light extraction efficiency compared to LEDs without such nanostructure.

FIG. 9B illustrates LED 930, in accordance with at least one embodiment. In at least one embodiment, LED 930 comprises multiple layers such as those described with reference to LED 900. In at least one embodiment, HMM 903 serves as a hole transport layer (HTL) and contains an optional hole injection layer (HIL). Compared to LED 900, in at least one embodiment, anode electrode 907 is integrated within outcoupling structure 938. In at least one embodiment, HMM 903 is a composite containing a mixture of metal and non-metallic regions resulting in a uniaxially anisotropic permittivity described by:

$$\overline{ε} = ( \begin{matrix}{ε}_{x} & 0 & 0 \\ 0 & {ε}_{y} & 0 \\ 0 & 0 & {ε}_{z}\end{matrix} )$$

that exhibits metallic (ε<0) and dielectric (ε>0) responses along orthogonal directions.

In at least one embodiment, LED 940 is similar to LED 930 but for locations of analog and cathode electrodes. In at least one embodiment, LED 940 comprises substrate 901, anode electrode 912, HMM 913, light emitting layer 914 (e.g., QD layer), electron transport layer (ETL) 915, electron injection layer (EIL) 916, and outcoupling structure 948 coupled as shown. In at least one embodiment, cathode is integrated within outcoupling structure 948.

In at least one embodiment, HMM 913 is configured to function as HTL and HIL. In at least one embodiment, HMM 913 is a charge injection layer. In at least one embodiment, EIL 916 is between cathode electrode 917 and HMM 913 to improve carrier injection efficiency. In at least one embodiment, outcoupling structure 948 is a nanostructure which is configured to function as a cathode and improve light outcoupling by improving light extraction efficiency compared to LEDs without such nanostructure.

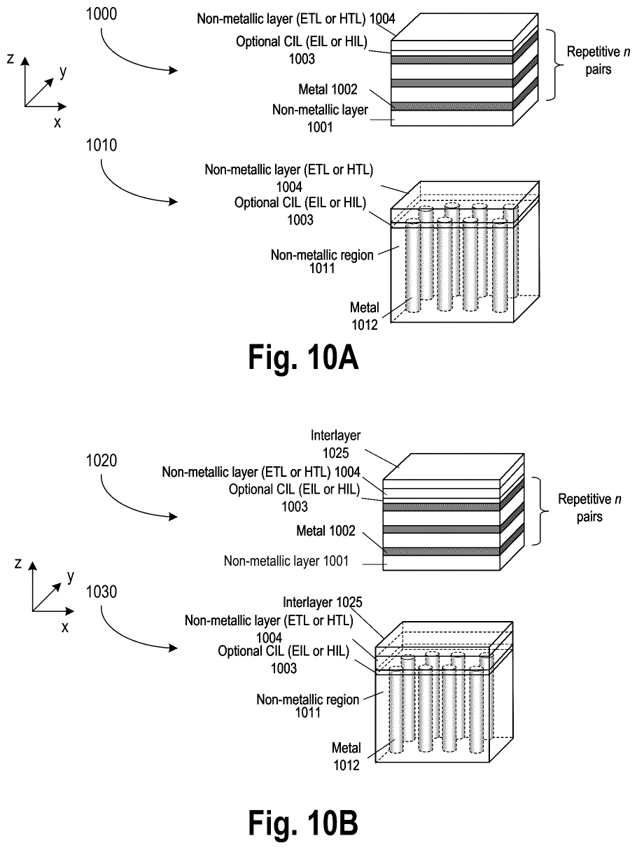

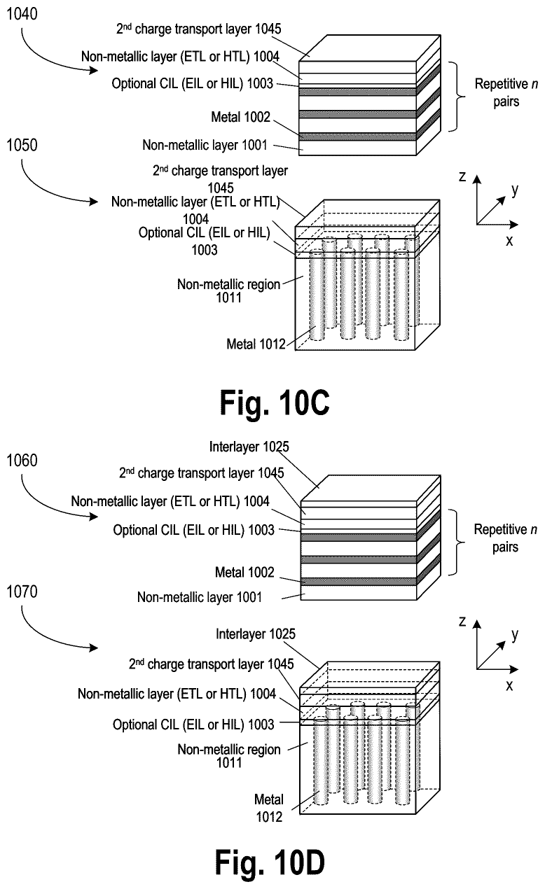

Using coordinates indicated in FIGS. 9A-C and FIGS. 10A-D, HMMs are classified as type I HMI with εₓ, ε_{y}>0 and ε_{z}<0, and type II HMM with εₓ, ε_{y}<0 and ε_{z}>0.

FIG. 9C illustrates LED 950, in accordance with at least one embodiment. In at least one embodiment, LED 950 is similar to LED 900 but without light outcoupling structure 908. Here, z-direction points to light-emitting direction and is perpendicular to surface of substrate 901.

In at least one embodiment, LED 960 is similar to LED 950 but for locations of analog and cathode electrodes. In at least one embodiment, LED 950 comprises substrate 901, anode electrode 912, HMM 913, light emitting layer 914 (e.g., QD layer), electron transport layer (ETL) 915, electron injection layer (EIL) 916, and cathode electrode 917 coupled as shown.

In at least one embodiment, HMM 913 is configured to function as HTL and HIL. In at least one embodiment, HMM 913 is a charge injection layer. In at least one embodiment, EIL 916 is between cathode electrode 917 and HMM 913 to improve carrier injection efficiency. In at least one embodiment, cathode electrode 917 is also configured to provide light outcoupling. In at least one embodiment, if a type I HMM is used in an LED, light outcoupling structure may not be used, as shown in FIG. 9C.

In at least one embodiment, cathode electrode 902 or cathode electrode 917 can be made of metal (e.g., 50-200 nm thick in z-direction), such as Al, Ag, Mg, Au, Ti, or conductive oxide, such as indium tin oxide (ITO). In at least one embodiment, thermal or e-beam evaporation is used to form cathode electrode 902 or cathode electrode 917.

In at least one embodiment, electron injection layer (EIL) 916 (e.g., 5 nm to 40 nm thick in z-direction) in contact with cathode electrode 917 can be made of alkali metal salts such as LiF, low work function metals such as Ca, Ba, and n-type material (e.g., the combination of electron transport material and electron donating material). In at least one embodiment, thermal or e-beam evaporation is used to form EIL 916.

In at least one embodiment, electron transport layer (ETL) 915 can be a single material layer made of metal oxide or metal nitride, such as ZnO or TiO₂ with a thickness ranging from, for example, 20 nm to 100 nm in a z-direction. In at least one embodiment, ETL 915 has a thickness of about 40 nm. In at least one embodiment, ETL 915 can be a double-layer or a multilayer structure. In at least one embodiment, when ETL 915 is a double-layer ETL, it comprises a first ETL (e.g., ZnO) and a second ETL (e.g., 1,3,5-tris(2-N-phenylbenzimidazolyl)benzene (TPBi)) of less than 10 nm on top of first ETL. In at least one embodiment, thickness of second ETL is about 5 nm. In at least one embodiment, when ETL 915 is a double-layer ETL, it comprises double-layer ETL which comprises a first ETL having ZnMgO layer (e.g., 5 nm to 15 nm) and a second ETL having ZnO layer (e.g., 20 nm to 40 nm) on top of first ETL. In at least one embodiment, metal oxide layers of ETL 915 can be formed by thermal or e-beam evaporation or sputter deposition. In at least one embodiment, metal oxide layers of ETL 915 can also be formed by spin-coating or printing metal oxide nanoparticle solutions or reactive metal oxide precursors. In at least one embodiment, organic materials can be coated using spin-coating or printing.

FIG. 10A illustrates portion 1000 of an LED, in accordance with at least one embodiment. In at least one embodiment, HMM/EIL/ETL composite layer, formed over a cathode electrode (not shown), is a stack structure comprising an HMM layer having non-metallic layer 1001 and metal layer 1002, an optional EIL 1003 (e.g., 5 nm to 40 nm thick along a z-direction), and a non-metallic ETL 1004 (e.g., 20 nm to 50 nm thick ZnO along z-direction). In at least one embodiment, non-metallic layer 1001 and metal layer 1002 are planar layers spreading mostly along x-y direction and less so along z-direction. In at least one embodiment, depending on location of anode electrode and cathode electrode, ETL 1004 may be replaced with HTL, and EIL 1003 may be replaced with HIL.

In at least one embodiment, non-metallic layer 1001 and metal layer 1003 form a stack of alternating metal and non-metallic multilayers. In at least one embodiment, metal of metal layer 1003 may be Al, Ag, Cu, Au, or Ti. In at least one embodiment, non-metallic material of non-metallic layer may be ZnO, TiO₂, NiO, CuO, MgO, WO₃, ITO, SnO, In₂O₃, InGaZnO, Si, Ge, GaAs, InGaAs, GaN, InGaN, InP, AlN, or TiN. In at least one embodiment, thickness of each pair of metal-non-metallic layers in z-direction may range from 4 nm to 50 nm, with the metal fill fraction ranging from 0% to 90%. In at least one embodiment, multilayered HMM may contain at least three repetitive pairs of metal-non-metallic layers. In at least one embodiment, metal oxide layers of non-metallic layer 1001 can be formed by thermal or e-beam evaporation or sputter deposition. In at least one embodiment, metal oxide layers of non-metallic layer 1001 can also be formed by spin-coating or printing metal oxide nanoparticle solutions or reactive metal oxide precursors. In at least one embodiment, organic materials can be coated using spin-coating or printing. In at least one embodiment, HMM layer can also be an epitaxial superlattice material.

In at least one embodiment, EIL 1003 can be alkali metal salts such as LiF, or low work function metals such as Ca, Ba, and n-type material (e.g., the combination of electron transport material and electron donating material). In at least one embodiment, ETL 1004 can be a single material layer made of metal oxide or metal nitride, such as ZnO, TiO₂.

In at least one embodiment, portion 1010 of LED is similar to portion 1000 but with non-planer non-metallic layer 1011 and metal layer 1012. In at least one embodiment, non-metallic layer 1011 (e.g., ZnO or NiO) and metal layer 1012 (e.g., Ag) are non-planar in that they spread mostly along z-direction and less so along x-y direction. In at least one embodiment, metal layer 1012 is an array of columns extending in z-direction. In at least one embodiment, non-metallic layer 1011 is material surrounding array of columns of metal layer 1012.

In at least one embodiment, non-planar structures of HMM layer comprise an array of metal nanorods surrounded by a host material formed of non-metallic layer 1011. In at least one embodiment, non-metallic layer 1011 includes metal oxides (e.g., ZnO, TiO₂, NiO, CuO, MgO, WO₃, ITO, SnO, In₂O₃, InGaZnO, or Al₂O₃), metal nitride (e.g., AlN, or TiN), semiconductor (e.g., Si, Ge, GaAs, InGaAs, GaN, InGaN, or InP), or dielectric material (e.g., SiO₂, polymer). In at least one embodiment, non-planar portion of HMM layer may be 50 nm to 200 nm thick in z-direction. In at least one embodiment, metal nanorod of metal layer 1012 is 5 nm to 50 nm wide. In at least one embodiment, metal fraction for non-planar HMM layer ranges from 0% to 90%. In at least one embodiment, metal nanorods may be Al, Ag, Cu, Au, or Ti. In at least one embodiment, non-planar HMM may be formed by combining metal electrodeposition through a thin film with a pore array formed by anodic etched oxide layers and block copolymer lithography.

FIG. 10B illustrates portion 1020 of an LED, in accordance with at least one embodiment. In at least one embodiment, portion 1020 is similar to portion 1000 but with an interface layer 1025 (e.g., 5 nm thick Al₂O₃, where thickness is along a z-direction) that may be included over ETL layer 1004 to eliminate exciton quenching. In at least one embodiment, portion 1030 is similar to portion 1010 but with interface layer 1025.

FIG. 10C illustrates portion 1040 of an LED, in accordance with at least one embodiment. In at least one embodiment, portion 1040 is similar to portion 1000 but with a second ETL 1045 (e.g., 3 nm to 20 nm thick in z-direction and comprising 1,3,5-tris(2-N-phenylbenzimidazolyl)benzene (TPBi)) that may be formed over ETL 1004 to improve current injection. In at least one embodiment, portion 1050 is similar to portion 1040 but with non-planer non-metallic layer 1011 and metal layer 1012.

FIG. 10D illustrates portion 1060 of an LED, in accordance with at least one embodiment. In at least one embodiment, portion 1060 includes second ETL 1045 over first ETL 1004 and interface layer 1025 over second ETL 1045. In at least one embodiment, portion 1070 is similar to portion 1060 but with non-planer non-metallic layer 1011 and metal layer 1012.

In at least one embodiment, emitting layer (e.g., 30 nm to 60 nm thick) is a layer of semiconductor colloidal quantum dots, carbon quantum dots, perovskite, or organic semiconductors. In at least one embodiment, emitting layer is a composite comprising one of the aforementioned materials embedded in a host material (e.g., poly (N-vinlycarbazole) (PVK)). In at least one embodiment, emitting layer can be formed by spin-coating, printing, or transfer process.

In at least one embodiment, hole transport layer (HTL) of 20 nm to 50 nm in thickness can be made of metal oxide (e.g., NiO) or organic materials, such as 4,4′-bis(carbazol-9-yl)biphenyl (CBP), poly[(9,9-dioctylfluorenyl-2,7-diyl)-co-(4,4′-(N-(4-sec-butylphenyl)diphenylamine))] (TFB), poly(4-butyl-phenyldiphenyl-amine) (poly-TPD) and/or poly-N-vinylcarbazole (PVK). In at least one embodiment, metal oxide layers can be formed by thermal or e-beam evaporation or sputter deposition. In at least one embodiment, metal oxide layers can also be formed by spin-coating or printing metal oxide nanoparticle solutions or reactive metal oxide precursors. In at least one embodiment, organic materials can be coated using spin-coating or printing.

In at least one embodiment, hole injection layer (HIL) of 5 nm to 40 nm in thickness in contact between anode and HTL may be formed of materials such as metal oxide (e.g., MoO₃), conductive polymer-based materials (e.g., poly thiophenes, poly(3,4-ethylenedioxythiophene) polystyrene sulfonate (PEDOT:PSS), poly anilines), combination of arylamine based hole transport host and electron accepting dopant, or strongly electron-accepting small organic molecules (e.g., perylene diimide, naphthalene-1,4:5,8-bis(dicarboximide), 2,5,8,11-tetrahexylperylene-3,4:9,10-bis(dicarboximide), tetracyanoquinodimethane, tetracyano-anthraquinodimethane, or 2,3,5,6-tetrafluoro-tetracyanoquinodimethan, and their derivatives). In at least one embodiment, strongly electron-accepting small organic molecules are molecules that may contain moieties, such as naphthalimide and viologen, to exhibit stronger electron-withdrawing properties. In at least one embodiment, metal oxide layers can be formed by thermal or e-beam evaporation or sputter deposition. In at least one embodiment, metal oxide layers can also be formed by spin-coating or printing metal oxide nanoparticle solutions or reactive metal oxide precursors. In at least one embodiment, organic materials can be coated using spin-coating or printing.

In at least one embodiment, HMM/HIL/HTL composite layer formed between the emitting layer and anode is a stack structure comprising an HMM layer, an optional HIL 1003 (5 nm to 40 nm thick), and a non-metallic HTL 1004 (e.g., 20 nm to 50 nm thick NiO) (portion 1010 of FIG. 10A). In at least one embodiment, interface layer 1025 (e.g., 5 nm Al₂O₃) may be included between HTL layer 1004 and emitting layer to eliminate exciton quenching (portion 1030 of FIG. 10B). In at least one embodiment, a second HTL 1045 (e.g., poly[bis(4-butypheny)-bis(phenyl)benzidine] (Poly-TPD), PVK, CBP) may be formed between the HTL 1004 and emitting layer to improve current injection (portion 1050 of FIG. 10C). In at least one embodiment, second HTL layer 1045 is formed over first HTL 1004 and an interface layer 1045 between the second HTL 1045 and emitting layer may be used in in an LED (portion 1070 of FIG. 10D).

In at least one embodiment, light-outcoupling structure on topmost layer of LED structure in FIG. 9A may be directly formed by a closely packed particle crystal fabricated by using a self-assembly process, as shown in FIG. 6A. In at least one embodiment, particles can be polystyrene particles with a size ranging from 100 nm to 800 nm. In at least one embodiment as shown in FIG. 6B, light-outcoupling structure may be created by molding a photo- or thermal-curable polymer using a mold with a periodic structure. In at least one embodiment, light-outcoupling structure can be formed by periodic pattern on top electrode where light emits to free space. In at least one embodiment, structure may be fabricated by a sequence of processes, including forming self-assembled particle crystal, shrinking particle size, metal deposition, and lift-off (FIG. 6C). In at least one embodiment, a similar process shown in FIG. 6D creates the periodic structure by using an imprinting process that transfers the periodic pattern on a polymer layer. As shown in FIG. 6E, in at least one embodiment, the light-outcoupling structure may be formed by imprinting a layer of inorganic nanoparticle dispersion or sol gel precursor, followed by thermal or UV curing.

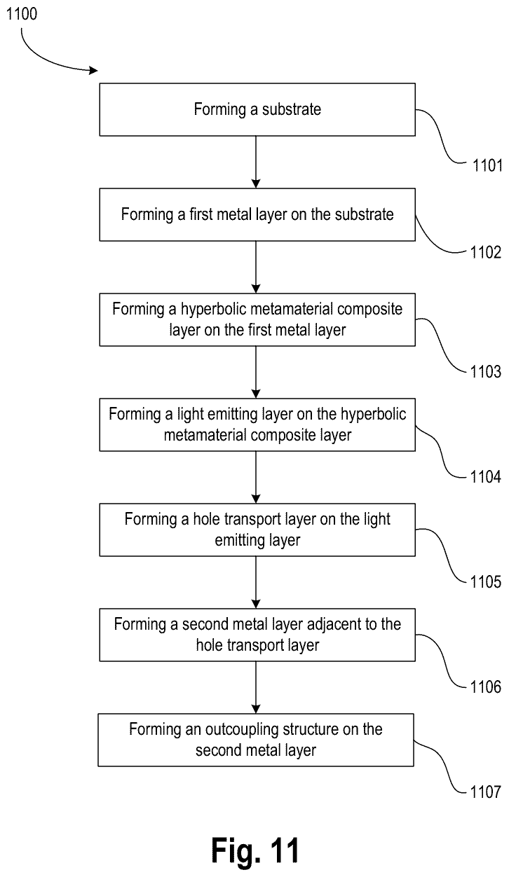

FIG. 11 illustrates method 1100 of forming an LED, in accordance with at least one embodiment. While various blocks of method 1100 are shown in a particular order, order can be modified. For example, some blocks may be performed in situ or out-of-order.

At block 1101, in at least one embodiment, a substrate is formed. In at least one embodiment, substrate is any suitable substrate for LEDs including SiO₂. At block 1102, in at least one embodiment, a first conductive layer is formed on the substrate, wherein first conductive layer (e.g., metal or ITO) is configured as a cathode.

At block 1103, in at least one embodiment, a hyperbolic metamaterial composite layer is formed on the cathode. In at least one embodiment, hyperbolic metamaterial composite layer includes a hyperbolic material and an electron transport layer. In at least one embodiment, forming hyperbolic material comprises forming an array of metal nanorods surrounded by a non-metallic host material. In at least one embodiment, non-metallic host material includes a metal oxide including one of ZnO, TiO₂, NiO, CuO, MgO, WO₃, ITO, SnO, In₂O₃, InGaZnO, or Al₂O₃. In at least one embodiment, non-metallic host material includes a metal nitride including one of AlN or TiN. In at least one embodiment, non-metallic host material includes a semiconductor including one of Si, Ge, GaAs, InGaAs, GaN, InGaN, or InP. In at least one embodiment, non-metallic host material includes dielectric material including one of SiO₂ or polymer.

At block 1104, in at least one embodiment, a light emitting layer is formed on hyperbolic metamaterial (HMM) composite layer. In at least one embodiment, material for HMM is according to material discussed herein.

At block 1105, in at least one embodiment, a hole transport layer is formed on the light emitting layer. At block 1106, in at least one embodiment, a second conductive layer is formed adjacent to the hole transport layer. In at least one embodiment, second conductive layer (e.g., metal or ITO) configured as an anode. At block 1107, in at least one embodiment, an outcoupling structure is formed on second conductive layer.

In at least one embodiment, method of forming an LED further comprises forming an electron injection layer between the hyperbolic material and the electron transport layer. In at least one embodiment, electron injection layer comprises one of alkali metal salt, Ca, Ba, or an n-type material. In at least one embodiment, electron injection layer has a thickness in a range of 5 nm to 40 nm. In at least one embodiment, forming an electron transport layer comprises forming a single material layer which includes a metal oxide or a metal nitride. In at least one embodiment, an electron transport layer has a thickness in a range of 20 nm to 200 nm.

Throughout the specification, and in the claims, the term “connected” means a direct connection, such as electrical, mechanical, or magnetic connection between the things that are connected, without any intermediary devices.

Here, “coupled” means a direct or indirect connection, such as a direct electrical, mechanical, or magnetic connection between the things that are connected or an indirect connection, through one or more passive or active intermediary devices.

Here, “adjacent” here generally refers to a position of a thing being next to (e.g., immediately next to or close to with one or more things between them) or adjoining another thing (e.g., abutting it).

Here “circuit” or “module” may refer to one or more passive and/or active components or software code that are arranged to cooperate with one another to provide a desired function.

Here, “signal” may refer to at least one current signal, voltage signal, magnetic signal, or data/clock signal. Here, meaning of “a,” “an,” and “the” include plural references. The meaning of “in” includes “in” and “on.”

Here, “analog signal” refers to any continuous signal for which the time varying feature (variable) of the signal is a representation of some other time varying quantity, i.e., analogous to another time varying signal.

Here, “digital signal” refers to a physical signal that is a representation of a sequence of discrete values (a quantified discrete-time signal), for example of an arbitrary bit stream, or of a digitized (sampled and analog-to-digital converted) analog signal.

Here, “substantially,” “close,” “approximately,” “near,” and “about,” generally refer to being within +/−10% of a target value.

Unless otherwise specified the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Here, “left,” “right,” “front,” “back,” “top,” “bottom,” “over,” “under,” and the like in the description and in the claims, if any, are used for descriptive purposes and not necessarily for describing permanent relative positions.

Reference in the specification to “an embodiment,” “one embodiment,” “some embodiments,” “at least one embodiment,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art considering the foregoing description. The embodiments of the disclosure are intended to embrace all such alternatives, modifications, and variations as to fall within the broad scope of the appended claims. Where specific details are set forth to describe example embodiments of the disclosure, it should be apparent to one skilled in the art that the disclosure can be practiced without, or with variation of, these specific details. The description is thus to be regarded as illustrative instead of limiting.

The following examples are provided that illustrate at least one embodiment. An example can be combined with any other example. As such, at least one embodiment can be combined with at least another embodiment without changing the scope of the disclosure.

Example 1 is an LED which comprises a substrate; a first conductive layer on the substrate, wherein the first conductive layer is configured as a cathode; a hyperbolic metamaterial composite layer on the cathode, wherein the hyperbolic metamaterial composite layer includes a hyperbolic material and an electron transport layer; a light emitting layer on the hyperbolic metamaterial composite layer; a hole transport layer on the light emitting layer; a second conductive layer adjacent to the hole transport layer, the second conductive layer configured as an anode; and an outcoupling structure on the second conductive layer. In at least one example, first conductive layer and/or second conductive layer comprise metal or transparent conductor like indium tin oxide (ITO).

Example 2 is an LED according to any example herein, in particular, example 1, wherein the hyperbolic material comprises an array of metal nanorods surrounded by a non-metallic host material.

Example 3 is an LED according to any example herein, in particular, example 2, wherein the non-metallic host material includes one of: a metal oxide including one of ZnO, TiO₂, NiO, CuO, MgO, WO₃, ITO, SnO, In₂O₃, InGaZnO, or Al₂O₃; a metal nitride including one of AlN or TiN; a semiconductor including one of Si, Ge, GaAs, InGaAs, GaN, InGaN, or InP; or dielectric material including one of SiO₂ or polymer.

Example 4 is an LED according to any example herein, in particular, example 1, wherein LED further comprises an electron injection layer between the hyperbolic material and the electron transport layer, wherein the electron injection layer comprises one of alkali metal salt, Ca, Ba, or an n-type material, wherein the electron injection layer has a thickness in a rage of 5 nm to 40 nm.

Example 5 is an LED according to any example herein, in particular, example 1, wherein the electron transport layer comprises a single material layer which includes a metal oxide or a metal nitride, wherein the electron transport layer has a thickness in a range of 20 nm to 200 nm.

Example 6 is an LED according to any example herein, in particular, example 1, wherein the metal oxide includes ZnO or TiO₂.

Example 7 is an LED according to any example herein, in particular, example 1, wherein the light emitting layer includes one of: semiconductor colloidal quantum dots; carbon quantum dots; perovskite; organic fluorophores; or organic semiconductors.

Example 8 is an LED according to any example herein, in particular, example 1, wherein the light emitting layer is a composite layer comprising one of: semiconductor colloidal quantum dots embedded in a host material; carbon quantum dots embedded in the host material; perovskite embedded in the host material; organic fluorophores in the host material; or organic semiconductors embedded in the host material.

Example 9 is an LED according to any example herein, in particular, example 1, wherein the hole transport layer comprises one of metal oxide or organic material, wherein the hole transport layer has a thickness in a range of 20 nm to 50 nm.

Example 10 is an LED according to any example herein, in particular, example 1, wherein the LED further comprises a hole injection layer on the hole transport layer, wherein the hole injection layer comprises one of: metal oxide including MoO₃; conductive polymer-based material including one of poly thiophenes, poly(3,4-ethylenedioxythiophene) polystyrene sulfonate (PEDOT:PSS), or poly anilines; a combination of arylamine based hole transport host and electron accepting dopant; or strongly electron-accepting small organic molecules.

Example 11 is an LED according to any example herein, in particular, example 2, wherein an individual metal nanorod of the array of metal nanorods includes one of Al, Ag, Cu, Au, Ti, or a combination of them.

Example 12 is an LED according to any example herein, in particular, example 1, wherein the first conductive layer comprises one of Al, Ag, Mg, Au, Tu, or conductive oxide, and wherein the first conductive layer has a thickness in a range of 50 nm to 200 nm.

Example 13 is an LED according to any example herein, in particular, example 12, wherein the conductive oxide includes indium tin oxide (ITO).

Example 14 is an LED according to any example herein, in particular, example 1, wherein the hyperbolic metamaterial composite layer comprises a stack of alternating metal and non-metallic layers.

Example 15 is an LED according to any example herein, in particular, example 14, wherein an alternating metal in the stack of alternating metal and non-metallic layers includes one of Al, Ag, Cu, Au, or Ti, and wherein a non-metallic layer in the stack of alternating metal and non-metallic layers includes one of: a metal oxide including one of ZnO, TiO₂, NiO, CuO, MgO, WO₃, ITO, SnO, In₂O₃, InGaZnO, or Al₂O₃; a metal nitride including one of AlN or TiN; a semiconductor including one of Si, Ge, GaAs, InGaAs, GaN, InGaN, or InP; or dielectric material including one of SiO₂ or polymer.

Example 16 is an LED according to any example herein, in particular, example 14, wherein the stack of alternating metal and non-metallic layers have a thickness in a range of 4 nm to 50 nm, with a metal fill fraction ranging from 0% to 90%.

Example 17 is an LED comprising: a substrate; a first conductive layer on the substrate, wherein the first conductive layer is configured as an anode; a hyperbolic metamaterial composite layer on the anode, wherein the hyperbolic metamaterial composite layer includes a hyperbolic metamaterial layer and a hole transport layer; a light emitting layer on the hyperbolic metamaterial composite layer; an electron transport layer on the light emitting layer; a second conductive layer adjacent to the electron transport layer, the second conductive layer configured as a cathode; and an outcoupling structure on the second conductive layer.

Example 18 is an LED according to any example herein, in particular, example 17, wherein the LED further comprises an electron injection layer between the second conductive layer and the electron transport layer, wherein the electron injection layer comprises one of alkali metal salt, Ca, Ba, or an n-type material, wherein the electron injection layer has a thickness in a rage of 5 nm to 40 nm.

Example 19 is an LED according to any example herein, in particular, example 18, wherein the n-type material includes a combination of an electron transport material and an electron donating material.

Example 20 is an LED according to any example herein, in particular, example 17, wherein the electron transport layer comprises a single material layer which includes a metal oxide or a metal nitride, wherein the electron transport layer has a thickness in a range of 20 nm to 200 nm.

Example 21 is an LED according to any example herein, in particular, example 20, wherein the metal oxide includes ZnO or TiO₂.

Example 22 is an LED according to any example herein, in particular, example 17, wherein the electron transport layer comprises a double-layer structure of a multi-layer structure.

Example 23 is an LED according to any example herein, in particular, example 22, wherein the double-layer structure comprises a first electron transport layer and a second electron transport layer, wherein the second electron transport layer is on the light emitting layer.

Example 24 is an LED according to any example herein, in particular, example 17, wherein the hyperbolic metamaterial layer comprises an array of metal nanorods surrounded by a non-metallic host material.

Example 25 is an LED according to any example herein, in particular, example 24, wherein the non-metallic host material includes one of: a metal oxide including one of ZnO, TiO₂, NiO, CuO, MgO, WO₃, ITO, SnO, In₂O₃, InGaZnO, or Al₂O₃; a metal nitride including one of AlN or TiN; a semiconductor including one of Si, Ge, GaAs, InGaAs, GaN, InGaN, InP; or dielectric material including one of SiO₂ or polymer.

Example 26 is an LED according to any example herein, in particular, example 17, wherein the light emitting layer includes one of: semiconductor colloidal quantum dots; carbon quantum dots; perovskite; organic fluorophores; or organic semiconductors.

Example 27 is an LED according to any example herein, in particular, example 17, wherein the light emitting layer is a composite layer comprising one of: semiconductor colloidal quantum dots embedded in a host material; carbon quantum dots embedded in the host material; perovskite embedded in the host material; organic fluorophores in the host material; or organic semiconductors embedded in a host material.

Example 28 is an LED according to any example herein, in particular, example 17, wherein the hyperbolic metamaterial composite layer comprises a hole transport layer which comprises one of metal oxide or organic material, wherein the hole transport layer has a thickness in a range of 20 nm to 50 nm.

Example 29 is an LED according to any example herein, in particular, example 28, wherein the hyperbolic metamaterial composite layer comprising a hole injection layer adjacent to the hole transport layer, wherein the hole injection layer comprises one of: a metal oxide including MoO₃; a conductive polymer-based material including one of poly thiophenes, poly(3,4-ethylenedioxythiophene) polystyrene sulfonate (PEDOT:PSS), or poly anilines; a combination of arylamine based hole transport host and electron accepting dopant; or strongly electron-accepting small organic molecules.

Example 30 is an LED according to any example herein, in particular, example 24, wherein an individual metal nanorod of the array of metal nanorods includes one of Al, Ag, Cu, Au, Ti, or a combination of them.

Example 31 is an LED according to any example herein, in particular, example 17, wherein the hyperbolic metamaterial layer comprises a stack of alternating metal and non-metallic layers.

Example 32 is an LED according to any example herein, in particular, example 31, wherein an alternating metal of the stack of alternating metal and non-metallic layers includes one of Al, Ag, Cu, Au, or Ti, and wherein a non-metallic layer of the stack of alternating metal and non-metallic layers includes one of: a metal oxide including one of ZnO, TiO₂, NiO, CuO, MgO, WO₃, ITO, SnO, In₂O₃, InGaZnO, or Al₂O₃; a metal nitride including one of AlN or TiN; a semiconductor including one of Si, Ge, GaAs, InGaAs, GaN, InGaN, or InP; or dielectric material including one of SiO₂ or polymer.

Example 33 is an LED according to any example herein, in particular, example 31, wherein the stack of alternating metal and non-metallic layers have a thickness in a range of 4 nm to 50 nm, with a metal fill fraction ranging from 0% to 90%.

Example 24 is a method for forming an LED, the method comprising: forming a substrate; forming a first conductive layer on the substrate, wherein the first conductive layer is configured as a cathode; forming a hyperbolic metamaterial composite layer on the cathode, wherein the hyperbolic metamaterial composite layer includes a hyperbolic material and an electron transport layer; forming a light emitting layer on the hyperbolic metamaterial composite layer; forming a hole transport layer on the light emitting layer; forming a second conductive layer adjacent to the hole transport layer, the second conductive layer configured as an anode; and forming an outcoupling structure on the second conductive layer.

Example 25 is a method according to any example herein, in particular, example 34, wherein forming the hyperbolic material comprises forming an array of metal nanorods surrounded by a non-metallic host material.

Example 26 is a method according to any example herein, in particular, example 25, wherein the non-metallic host material includes one of: a metal oxide including one of ZnO, TiO₂, NiO, CuO, MgO, WO₃, ITO, SnO, In₂O₃, InGaZnO, or Al₂O₃; a metal nitride including one of AlN or TiN; a semiconductor including one of Si, Ge, GaAs, InGaAs, GaN, InGaN, or InP; or dielectric material including one of SiO₂ or polymer.

Example 27 is a method according to any example herein, in particular, example 24, further comprising forming an electron injection layer between the hyperbolic material and the electron transport layer, wherein the electron injection layer comprises one of alkali metal salt, Ca, Ba, or an n-type material, wherein the electron injection layer has a thickness in a rage of 5 nm to 40 nm.

Example 28 is a method according to any example herein, in particular, example 24, wherein forming the electron transport layer comprises forming a single material layer which includes a metal oxide or a metal nitride, wherein the electron transport layer has a thickness in a range of 20 nm to 200 nm.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

We claim:

1. An LED comprising:
a substrate;
a first conductive layer on the substrate, wherein the first conductive layer is configured as a cathode;
a hyperbolic metamaterial composite layer on the cathode, wherein the hyperbolic metamaterial composite layer includes a hyperbolic material and an electron transport layer;
a light emitting layer on the hyperbolic metamaterial composite layer;
a hole transport layer on the light emitting layer;
a second conductive layer adjacent to the hole transport layer, the second conductive layer configured as an anode; and
an outcoupling structure on the second conductive layer.

2. The LED of claim 1, wherein the hyperbolic material comprises an array of metal nanorods surrounded by a non-metallic host material.

3. The LED of claim 2, wherein the non-metallic host material includes one of:
a metal oxide including one of ZnO, TiO₂, NiO, CuO, MgO, WO₃, ITO, SnO, In₂O₃, InGaZnO, or Al₂O₃;
a metal nitride including one of AlN or TiN;
a semiconductor including one of Si, Ge, GaAs, InGaAs, GaN, InGaN, or InP; or
dielectric material including one of SiO₂ or polymer.

4. The LED of claim 1, comprises an electron injection layer between the hyperbolic material and the electron transport layer, wherein the electron injection layer comprises one of alkali metal salt, Ca, Ba, or an n-type material, wherein the electron injection layer has a thickness in a rage of 5 nm to 40 nm.

5. The LED of claim 1, wherein the electron transport layer comprises a single material layer which includes a metal oxide or a metal nitride, wherein the electron transport layer has a thickness in a range of 20 nm to 200 nm.

6. The LED of claim 5, wherein the metal oxide includes ZnO or TiO₂.

7. The LED of claim 1, wherein the light emitting layer includes one of:
semiconductor colloidal quantum dots;
carbon quantum dots;
perovskite;
organic fluorophores; or
organic semiconductors.

8. The LED of claim 1, wherein the light emitting layer is a composite layer comprising one of:
semiconductor colloidal quantum dots;
carbon quantum dots;
perovskite;
organic fluorophores; or
organic semiconductors.

9. The LED of claim 1, wherein the hole transport layer comprises one of metal oxide or organic material, wherein the hole transport layer has a thickness in a range of 20 nm to 50 nm.

10. The LED of claim 1 comprising a hole injection layer on the hole transport layer, wherein the hole injection layer comprises one of:
metal oxide including MoO₃;
conductive polymer-based material including one of poly thiophenes, poly(3,4-ethylenedioxythiophene) polystyrene sulfonate (PEDOT:PSS), or poly anilines;
a combination of arylamine based hole transport host and electron accepting dopant; or
strongly electron-accepting small organic molecules.

11. The LED of claim 2, wherein an individual metal nanorod of the array of metal nanorods includes one of Al, Ag, Cu, Au, Ti, or a combination of them.

12. The LED of claim 1, wherein the first conductive layer comprises one of Al, Ag, Mg, Au, Tu, or conductive oxide, and wherein the first conductive layer has a thickness in a range of 50 nm to 200 nm.

13. The LED of claim 12, wherein the conductive oxide includes indium tin oxide (ITO).

14. The LED of claim 1, wherein the hyperbolic metamaterial composite layer comprises a stack of alternating metal and non-metallic layers.

15. The LED of claim 14, wherein an alternating metal in the stack of alternating metal and non-metallic layers includes one of Al, Ag, Cu, Au, or Ti, and wherein a non-metallic layer in the stack of alternating metal and non-metallic layers includes one of:
a metal oxide including one of ZnO, TiO₂, NiO, CuO, MgO, WO₃, ITO, SnO, In₂O₃, InGaZnO, or Al₂O₃;
a metal nitride including one of AlN or TiN;
a semiconductor including one of Si, Ge, GaAs, InGaAs, GaN, InGaN, or InP; or
dielectric material including one of SiO₂ or polymer.

16. The LED of claim 14, wherein the stack of alternating metal and non-metallic layers have a thickness in a range of 4 nm to 50 nm, with a metal fill fraction ranging from 0% to 90%.

17. An LED comprising:
a substrate;
a first conductive layer on the substrate, wherein the first conductive layer is configured as an anode;
a hyperbolic metamaterial composite layer on the anode, wherein the hyperbolic metamaterial composite layer includes a hyperbolic metamaterial layer and a hole transport layer;
a light emitting layer on the hyperbolic metamaterial composite layer;
an electron transport layer on the light emitting layer;
a second conductive layer adjacent to the electron transport layer, the second conductive layer configured as a cathode; and
an outcoupling structure on the second conductive layer.

18. The LED of claim 17, comprises an electron injection layer between the second conductive layer and the electron transport layer, wherein the electron injection layer comprises one of alkali metal salt, Ca, Ba, or an n-type material, wherein the electron injection layer has a thickness in a rage of 5 nm to 40 nm.

19. The LED of claim 18, wherein the n-type material includes a combination of an electron transport material and an electron donating material.

20. A method for forming an LED, the method comprising:
forming a substrate;
forming a first conductive layer on the substrate, wherein the first conductive layer is configured as a cathode;
forming a hyperbolic metamaterial composite layer on the cathode, wherein the hyperbolic metamaterial composite layer includes a hyperbolic material and an electron transport layer;
forming a light emitting layer on the hyperbolic metamaterial composite layer;
forming a hole transport layer on the light emitting layer;
forming a second conductive layer adjacent to the hole transport layer, the second conductive layer configured as an anode; and
forming an outcoupling structure on the second conductive layer.
